(19) United States
(12) Patent Application Publication
(10) Pub. No.: US 2026/0147272 A1
(43) Pub. Date: May 28, 2026

(54) Method and System for Shaping Partial Fields

(71) Applicant: CANON KABUSHIKI KAISHA, Tokyo (JP)

(72) Inventors: Daniel Ironside, Austin, TX (US); Steven T. Jenkins, Round Rock, TX (US)

(21) Appl. No.: 18/956,780

(22) Filed: Nov. 22, 2024

(51) Int. Cl. G03F 7/00

(52) U.S. Cl. CPC G03F 7/0002

(57) ABSTRACT

An imprinting method includes reducing a distance between a template and a substrate. While reducing the distance the method includes controlling a state of one or more of the template and substrate, and detecting intensity of light reflected from both the template and the substrate. The method includes determining whether a predetermined light condition has been satisfied based on the detected light intensity, in a case of determining that the predetermined light condition has been satisfied, determining an estimated initial contact point between the template and the substrate based on the detected light intensity, and in a case that a difference between the estimated initial contact point and a target initial contact point is greater than a predetermined threshold amount, changing the state based on the difference.

### BACKGROUND

### Technical Field

The present disclosure relates to photomechanical shaping systems (e.g., Nanoimprint Lithography and Inkjet Adaptive Planarization). In particular, the present disclosure relates to methods of imprinting (also referred to as shaping) full fields, partial fields, and small partial fields on a substrate.

### Description of the Related Art

Nano-fabrication includes the fabrication of very small structures that have features on the order of 100 nanometers or smaller. One application in which nano-fabrication has had a sizeable impact is in the fabrication of integrated circuits. The semiconductor processing industry continues to strive for larger production yields while increasing the circuits per unit area formed on a substrate. Improvements in nano-fabrication include providing greater process control and/or improving throughput while also allowing continued reduction of the minimum feature dimensions of the structures formed.

One nano-fabrication technique in use today is commonly referred to as nanoimprint lithography. Nanoimprint lithography is useful in a variety of applications including, for example, fabricating one or more layers of integrated devices by shaping a film on a substrate. Examples of an integrated device include but are not limited to CMOS logic, microprocessors, NAND Flash memory, NOR Flash memory, DRAM memory, MRAM, 3D cross-point memory, Re-RAM, Fe-RAM, STT-RAM, MEMS, and the like. Exemplary nanoimprint lithography systems and processes are described in detail in numerous publications, such as U.S. Pat. Nos. 8,349,241, 8,066,930, and 6,936,194, all of which are hereby incorporated by reference herein.

The nanoimprint lithography technique disclosed in each of the aforementioned patents describes the shaping of a film on a substrate by the formation of a relief pattern in a formable material (polymerizable) layer. The shape of this film may then be used to transfer a pattern corresponding to the relief pattern into and/or onto an underlying substrate.

The shaping process uses a template spaced apart from the substrate. The formable material is applied onto the substrate. The template is brought into contact with the formable material that may have been deposited as a drop pattern using the formable material to spread and fill the space between the template and the substrate. The template may be used to imprint full fields and/or partial fields on the substate. The formable material is solidified to form a film that has a shape (pattern) conforming to a shaping surface of the template. After solidification, the template is separated from the solidified layer such that the template and the substrate are spaced apart.

The substrate and the solidified layer may then be subjected to known steps and processes for device (article) fabrication, including, for example, curing, oxidation, layer formation, deposition, doping, planarization, etching, formable material removal, dicing, bonding, and packaging, and the like. For example, the pattern on the solidified layer may be subjected to an etching process that transfers the pattern into the substrate.

When imprinting partial fields in particular, it can be difficult to achieve a target initial contact point. The target initial contact point is a predetermined location for the template to initially come into contact with the substrate to achieve optimal filling, low defectivity, and overlay performance. However, it has been found that even when implementing predetermined control parameters (discussed in more detail below) to attempt to achieve the target initial contact point, the actual initial contact point may deviate by an amount that negatively impacts filling performance. Model based approaches used in the past can become ineffective when there is large wafer to wafer variation. Thus, there is a need in the art for a method of imprinting in which the actual initial contact point will be closer to the target initial contact point to improve filling performance and product quality.

### SUMMARY

An imprinting method includes reducing a distance between a template and a substrate, while reducing the distance: controlling a state of one or more of the template and substrate, and detecting intensity of light reflected from both the template and the substrate, determining whether a predetermined light condition has been satisfied based on the detected light intensity, in a case of determining that the predetermined light condition has been satisfied, determining an estimated initial contact point between the template and the substrate based on the detected light intensity, and in a case that a difference between the estimated initial contact point and a target initial contact point is greater than a predetermined threshold amount, changing the state based on the difference.

A method of manufacturing an article includes dispensing formable material on a substrate, reducing a distance between a template and the substrate, while reducing the distance: controlling a state of one or more of the template and substrate, and detecting intensity of light reflected from both the template and the substrate, determining whether a predetermined light condition has been satisfied based on the detected light intensity, in a case of determining that the predetermined light condition has been satisfied, determining an estimated initial contact point between the template and the substrate based on the detected light intensity, in a case that a difference between the estimated initial contact point and a target initial contact point is greater than a predetermined threshold amount, changing the state based on the difference, bringing the template into contact with the formable material, exposing the formable material under the template to actinic radiation, processing the substrate, and forming the article from the processed substrate.

A imprinting system includes one or more memory, and one or more processors configured to: reduce a distance between a template and a substrate, while reducing the distance: control a state of one or more of the template and substrate, and detect intensity of light reflected from both the template and the substrate, determine whether a predetermined light condition has been satisfied based on the detected light intensity, in a case of determining that the predetermined light condition has been satisfied, determine an estimated initial contact point between the template and the substrate based on the detected light intensity, and in a case that a difference between the estimated initial contact point and a target initial contact point is greater than a predetermined threshold amount, change the state based on the difference.

These and other objects, features, and advantages of the present disclosure will become apparent upon reading the following detailed description of exemplary embodiments of the present disclosure, when taken in conjunction with the appended drawings, and provided claims.

### BRIEF DESCRIPTION OF THE FIGURES

So that features and advantages of the present invention can be understood in detail, a more particular description of embodiments of the invention may be had by reference to the embodiments illustrated in the appended drawings. It is to be noted, however, that the appended drawings only illustrate typical embodiments of the invention and are therefore not to be considered limiting of its scope, for the invention may admit to other equally effective embodiments.

FIG. 1 is an illustration of an exemplary nanoimprint lithography system having a template with a mesa spaced apart from a substrate as used in an embodiment.

FIGS. 2A-B are illustrations of exemplary templates that may be used in an embodiment.

FIG. 3 is a flowchart illustrating an exemplary imprinting method as used in an embodiment.

FIGS. 4A-B are illustrations of layouts of fields on substrates as used in an embodiment.

FIGS. 4C-D are illustrations of a small partial field on substrate as used in an embodiment.

FIGS. 5A-F are illustrations of states of a substrate and a template as used in an embodiment.

FIG. 6 is a flowchart illustrating an imprinting method according to example embodiment.

FIG. 7 is a flowchart illustrating additional detail of the imprinting method of FIG. 6.

FIG. 8A is an illustration of a template and substrate for imprinting a partial field separated by a distance.

FIG. 8B is an image of the template and substrate at the position of FIG. 8A when visible light is emitted thereon.

FIG. 9A is an illustration of a template and substrate for imprinting a partial field separated by a distance that is smaller than the distance of FIG. 8A.

FIG. 9B is an image of the template and substrate at the position of FIG. 9B when visible light is emitted thereon.

FIG. 10A is an illustration of a template and substrate for imprinting a partial field separated by a distance that is smaller than the distance of FIG. 9A.

FIG. 10B is an image of the template and substrate at the position of FIG. 10A when visible light is emitted thereon.

FIG. 11A is an illustration of a template and substrate for imprinting a partial field separated by a distance that is smaller than the distance of FIG. 10A.

FIG. 11B is an image of the template and substrate at the position of FIG. 11A when visible light is emitted thereon.

FIG. 12A is an illustration of a template and substrate for imprinting a partial field separated by a distance that is smaller than the distance of FIG. 11A.

FIG. 12B is an image of the template and substrate at the position of FIG. 12A when visible light is emitted thereon.

FIGS. 13A and 13B show image processing of the image of FIG. 12B.

FIG. 13C shows the result of this image analysis process being performed on 6 frames as the template is approaching the substrate.

FIG. 14 shows a frame statistic varying with frame number.

FIGS. 15A and 15B show timing charts for performing the imprinting method of FIG. 3.

Throughout the figures, the same reference numerals and characters, unless otherwise stated, are used to denote like features, elements, components, or portions of the illustrated embodiments. Moreover, while the subject disclosure will now be described in detail with reference to the figures, it is done so in connection with the illustrative exemplary embodiments. It is intended that changes and modifications can be made to the described exemplary embodiments without departing from the true scope and spirit of the subject disclosure as defined by the appended claims.

### DETAILED DESCRIPTION

The nanoimprint lithography technique can be used in a step and repeat manner to shape a film with a template in a plurality of fields across a substrate. The substrate and a patterning area/shaping surface (mesa) of a template may have different shapes and sizes. For example, the substrate may have a region to be patterned that is circular, elliptical, polygonal, or some other shape. While the mesa is typically smaller than the substrate and has a different shape than the substrate. The substrate is divided into a plurality of full fields and a plurality of partial fields. The full fields are the same size as the mesa. That is the entire surface area of the mesa is equal to the area of a full field. In other words, for a full field, the total surface area of the shaping surface overlaps the substrate. The partial fields are those fields on the edge of the substrate in which the edge of the region to be patterned on the substrate intersects with the patterning area of the mesa. These fields may be divided into multiple categories based on their shape and/or area relative to the full field. For a partial field, only a portion of the surface area of the mesa is equal to the area of the area of a partial field. In other words, for a partial field, the shaping surface overlaps an edge of the substrate.

The partial fields having an area that is less than the an area of a full field area (e.g., the partial field area may be 5% to 99% of the full field area or 10% to 95% of the full field area) tend to have higher defectivity and/or higher processing time than full fields. In addition, small partial fields which may have an area of 50% or less of a full field area or 35% or less than a full field area, are particularly challenging. That is, a small partial field has an area that is equal to 50% or less (or 35% or less) of the area of a full field, which is 50% or less (or 35% or less) of the entire surface area of the mesa. It is desirable to lower defectivity and/or higher processing time for partial fields and small partial fields. The applicant has found that the defectivity and/or higher processing time for small partial fields can be reduced if the initial contact point (ICP) is well chosen. One method of choosing the ICP was described in U.S. Pat. No. 11,614,693.

However, even when a target ICP is well chosen, the applicant has found that, it is difficult to develop control parameters that will achieve an actual ICP that is within an acceptable deviation from the target ICP, in particular for partial fields and small partial fields. What is needed is a method of imprinting in which the actual ICP will be closer to the target ICP to improve filling performance.

### Shaping System

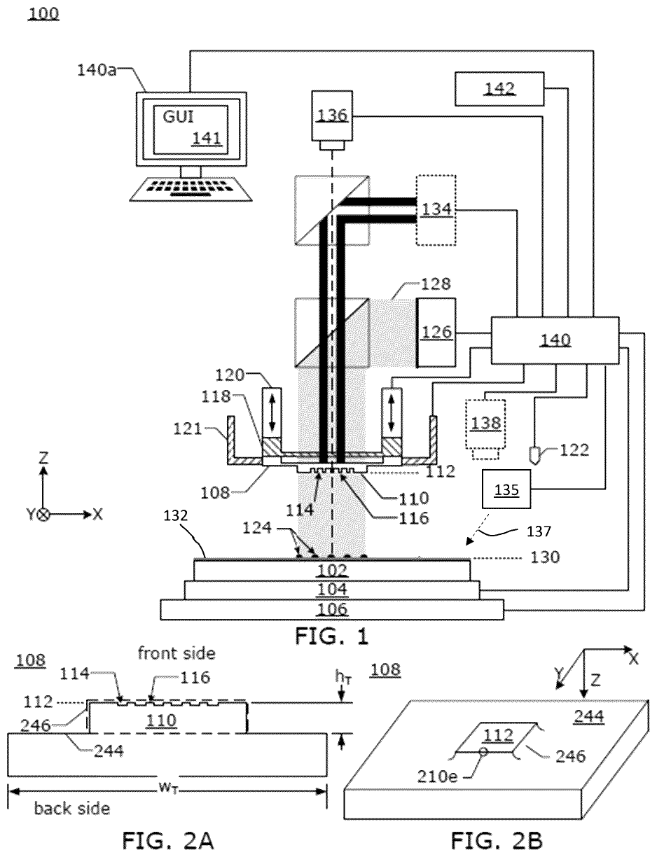

FIG. 1 is an illustration of a shaping system 100 (for example a nanoimprint lithography system or inkjet adaptive planarization system) in which an embodiment may be implemented. The shaping system 100 is used to produce an imprinted (shaped) film on a substrate 102. The substrate 102 may be coupled to a substrate chuck 104. The substrate chuck 104 may be but is not limited to a vacuum chuck, pin-type chuck, groove-type chuck, electrostatic chuck, electromagnetic chuck, and/or the like.

The substrate 102 and the substrate chuck 104 may be further supported by a substrate positioning stage 106. The substrate positioning stage 106 may provide translational and/or rotational motion along one or more of the positional axes x, y, and z, and rotational axes θ, ψ, and φ. The substrate positioning stage 106, the substrate 102, and the substrate chuck 104 may also be positioned on a base (not shown). The substrate positioning stage may be a part of a positioning system. In an alternative embodiment, the substrate chuck 104 may be attached to the base.

Spaced-apart from the substrate 102 is a template 108 (also referred to as a superstrate). The template 108 may include a body having a mesa (also referred to as a mold) 110 extending towards the substrate 102 on a front side of the template 108. The mesa 110 may have a shaping surface 112 thereon also on the front side of the template 108. The shaping surface 112, also known as a patterning surface, is the surface of the template that shapes the formable material 124. The mesa, and more particularly, the shaping surface 112, has a surface area facing the substrate 102. In an embodiment, the shaping surface 112 is planar and is used to planarize the formable material. Alternatively, the template 108 may be formed without the mesa 110, in which case the surface of the template facing the substrate 102 is equivalent to the mesa 110 and the shaping surface 112 is that surface of the template 108 facing the substrate 102.

The template 108 may be formed from such materials including, but not limited to, fused-silica, quartz, silicon, organic polymers, siloxane polymers, borosilicate glass, fluorocarbon polymers, metal, hardened sapphire, and/or the like. The shaping surface 112 may have features defined by a plurality of spaced-apart template recesses 114 and/or template protrusions 116. The shaping surface 112 defines a pattern that forms the basis of a pattern to be formed on the substrate 102. In an alternative embodiment, the shaping surface 112 is featureless in which case a planar surface is formed on the substrate. In an alternative embodiment, the shaping surface 112 is featureless and the same size as the substrate and a planar surface is formed across the entire substrate.

The template 108 may be coupled to a template chuck 118. The template chuck 118 may be, but is not limited to, vacuum chuck, pin-type chuck, groove-type chuck, electrostatic chuck, electromagnetic chuck, and/or other similar chuck types. The template chuck 118 may be configured to apply stress, pressure, and/or strain to template 108 that varies across the template 108. The template chuck 118 may include a template magnification control system 121. The template magnification control system 121 may include piezoelectric actuators (or other actuators) which can squeeze and/or stretch different portions of the template 108. The template chuck 118 may include a system such as a zone based vacuum chuck, an actuator array, a pressure bladder, etc. which can apply a pressure differential to a back surface of the template causing the template to bend and deform.

The template chuck 118 may be coupled to a shaping head 120 which is a part of the positioning system. The shaping head 120 may be moveably coupled to a bridge. The shaping head 120 may include one or more actuators such as voice coil motors, piezoelectric motors, linear motor, nut and screw motor, etc., which are configured to move the template chuck 118 relative to the substrate in at least the z-axis direction, and potentially other directions (e.g., positional axes x, and y, and rotational axes 0, w, and @).

The shaping system 100 may further comprise a fluid dispenser 122. The fluid dispenser 122 may also be moveably coupled to the bridge. In an embodiment, the fluid dispenser 122 and the shaping head 120 share one or more or all of the positioning components. In an alternative embodiment, the fluid dispenser 122 and the shaping head 120 move independently from each other. The fluid dispenser 122 may be used to deposit liquid formable material 124 (e.g., polymerizable material) onto the substrate 102 in a drop pattern. Additional formable material 124 may also be added to the substrate 102 using techniques, such as, drop dispense, spin-coating, dip coating, chemical vapor deposition (CVD), physical vapor deposition (PVD), thin film deposition, thick film deposition, and/or the like prior to the formable material 124 being deposited onto the substrate 102. The formable material 124 may be dispensed upon the substrate 102 before and/or after a desired volume is defined between the shaping surface 112 and the substrate 102 depending on design considerations. The formable material 124 may comprise a mixture including a monomer as described in U.S. Pat. Nos. 7,157,036 and 8,076,386, both of which are herein incorporated by reference.

Different fluid dispensers 122 may use different technologies to dispense formable material 124. When the formable material 124 is jettable, ink jet type dispensers may be used to dispense the formable material. For example, thermal ink jetting, microelectromechanical systems (MEMS) based ink jetting, valve jet, and piezoelectric ink jetting are common techniques for dispensing jettable liquids.

The shaping system 100 may further comprise a curing system that induces a phase change in the liquid formable material into a solid material whose top surface is determined by the shape of the shaping surface 112. The curing system may include at least a radiation source 126 that directs actinic energy along an exposure path 128. The shaping head and the substrate positioning stage 106 may be configured to position the template 108 and the substrate 102 in superimposition with the exposure path 128. The radiation source 126 sends the actinic energy along the exposure path 128 after the template 108 has contacted the formable material 124. FIG. 1 illustrates the exposure path 128 when the template 108 is not in contact with the formable material 124, this is done for illustrative purposes so that the relative position of the individual components can be easily identified. An individual skilled in the art would understand that exposure path 128 would not substantially change when the template 108 is brought into contact with the formable material 124. In an embodiment, the actinic energy may be directed through both the template chuck 118 and the template 108 into the formable material 124 under the template 108. In an embodiment, the actinic energy produced by the radiation source 126 is UV light that induces polymerization of monomers in the formable material 124.

The shaping system 100 may further comprise a field camera 136 that is positioned to view the spread of formable material 124 after the template 108 has contacted the formable material 124. FIG. 1 illustrates an optical axis of the field camera's imaging field as a dashed line. As illustrated in FIG. 1 the shaping system 100 may include one or more optical components (dichroic mirrors, beam combiners, prisms, lenses, mirrors, etc.) which combine the actinic radiation with light to be detected by the field camera. The field camera 136 may be configured to detect the spread of formable material under the template 108. Thus, the field camera may also be referred to as a spread camera. The optical axis of the field camera 136 as illustrated in FIG. 1 is straight but may be bent by one or more optical components. The field camera 136 may include one or more of: a CCD; a sensor array; a line camera; and a photodetector which are configured to gather light that has a wavelength that shows a contrast between regions underneath the template 108 that are in contact with the formable material, and regions underneath the template 108 which are not in contact with the formable material 124. The field camera 136 may be configured to gather monochromatic images of visible light. The field camera 136 may be configured to provide images of the spread of formable material 124 underneath the template 108; the separation of the template 108 from cured formable material; and can be used to keep track of the imprinting (shaping) process. The field camera 136 may also be configured to measure interference fringes, which change as the formable material spreads 124 between the gap between the shaping surface 112 and the substrate surface 130. The shape of interference fringes can be dependent upon deformation of the shaping surface 112 relative to a shape of the substrate surface 130.

The shaping system 100 may further comprise a droplet inspection system 138 that is separate from the field camera 136. The droplet inspection system 138 may include one or more of a CCD, a camera, a line camera, and a photodetector. The droplet inspection system 138 may include one or more optical components such as lenses, mirrors, optical diaphragms, apertures, filters, prisms, polarizers, windows, adaptive optics, and/or light sources. The droplet inspection system 138 may be positioned to inspect droplets prior to the shaping surface 112 contacting the formable material 124 on the substrate 102. In an alternative embodiment, the field camera 136 may be configured as a droplet inspection system 138 and used prior to the shaping surface 112 contacting the formable material 124.

The shaping system 100 may further include a thermal radiation source 134 which may be configured to provide a spatial distribution of thermal radiation to one or both of the template 108 and the substrate 102. The thermal radiation source 134 may include one or more sources of thermal electromagnetic radiation that will heat up one or both of the substrate 102 and the template 108 and does not cause the formable material 124 to solidify. The thermal radiation source 134 may include a SLM such as a digital micromirror device (DMD), Liquid Crystal on Silicon (LCoS), Liquid Crystal Device (LCD), etc., to modulate the spatio-temporal distribution of thermal radiation. The shaping system 100 may further comprise one or more optical components which are used to combine the actinic radiation, the thermal radiation, and the radiation gathered by the field camera 136 onto a single optical path that intersects with the imprint field when the template 108 comes into contact with the formable material 124 on the substrate 102. The thermal radiation source 134 may send the thermal radiation along a thermal radiation path (which in FIG. 1 is illustrated as 2 thick dark lines) after the template 108 has contacted the formable material 124. FIG. 1 illustrates the thermal radiation path when the template 108 is not in contact with the formable material 124, this is done for illustrative purposes so that the relative position of the individual components can be easily identified. An individual skilled in the art would understand that the thermal radiation path would not substantially change when the template 108 is brought into contact with the formable material 124. In FIG. 1 the thermal radiation path is shown terminating at the template 108, but it may also terminate at the substrate 102. In an alternative embodiment, the thermal radiation source 134 is underneath the substrate 102, and thermal radiation path is not combined with the actinic radiation and the visible light.

The shaping system 100 may further include a light source 135 which may emit measurement light 137. The light source 135 may be configured to emit visible light toward the substrate and template when the template and the substrate are near each other, as will be discussed in more detail below. The light 137 may be 470 nm light, for example. The measurement light 137 may be monochromatic. The light source 135 may be an array of light emitting diodes. The light source 135 may include one or more lasers. While the light source 135 is shown as a separate element in FIG. 1, in another example embodiment the light source 135 may be integrated into the thermal radiation source 134 or integrated into the radiation source 126. The field camera/spread camera 136 may be configured to capture images of the template and substrate as the measurement light 137 is reflected by the template and substrate as discussed below. The shaping system 100 may include one or more optical components which guide measurement light 137 through the shaping surface 112, reflects off the substrate surface 130 back through the shaping surface 112 and is received by the field camera 136. The one or more optical components can also guide measurement light 137 that is reflected off the shaping surface 112 to the field camera 136. Examples of the one or more optical components include but are not limited to: lenses, mirrors, optical diaphragms, apertures, filters, optical combiners, optical splitters, prisms, polarizers, windows, adaptive optics, etc.

Prior to the formable material 124 being dispensed onto the substrate, a substrate coating 132 may be applied to the substrate 102. In an embodiment, the substrate coating 132 may be an adhesion layer. In an embodiment, the substrate coating 132 may be applied to the substrate 102 prior to the substrate being loaded onto the substrate chuck 104. In an alternative embodiment, the substrate coating 132 may be applied to substrate 102 while the substrate 102 is on the substrate chuck 104. In an embodiment, the substrate coating 132 may be applied by spin coating, dip coating, drop dispense, slot dispense, etc. In an embodiment, the substrate 102 may be a semiconductor wafer, a glass wafer, a sapphire wafer, or some other material. In another embodiment, the substrate 102 may be a blank template (replica blank) that may be used to create a daughter template after being imprinted.

The shaping system 100 may include an imprint field atmosphere control system such as gas and/or vacuum system, an example of which is described in U.S. Patent Publication No. 2010/0096764 and U.S. Pat. No. 10,895,806 which are hereby incorporated by reference. The gas and/or vacuum system may include one or more of: pumps, valves, solenoids, gas sources, gas tubing, etc. which are configured to cause one or more different gases to flow at different times and different regions. The gas and/or vacuum system may be connected to a first gas transport system that transports gas to and from the edge of the substrate 102 and controls the imprint field atmosphere by controlling the flow of gas at the edge of the substrate 102. The gas and/or vacuum system may be connected to a second gas transport system that transports gas to and from the edge of the template 108 and controls the imprint field atmosphere by controlling the flow of gas at the edge of the template 108. The gas and/or vacuum system may be connected to a third gas transport system that transports gas to and from the top of the template 108 and controls the imprint field atmosphere by controlling the flow of gas through the template 108. One or more of the first, second, and third gas transport systems may be used in combination or separately to control the flow of gas in and around the imprint field.

The shaping system 100 may be regulated, controlled, and/or directed by one or more processors 140 (controller) in communication with one or more components and/or subsystems such as the substrate chuck 104, the substrate positioning stage 106, the template chuck 118, the shaping head 120, the fluid dispenser 122, the radiation source 126, the thermal radiation source 134, the light source 135, the field camera 136, imprint field atmosphere control system, and/or the droplet inspection system 138. The processor 140 may operate based on instructions in a computer readable program stored in a non-transitory computer readable memory 142. The processor 140 may be or include one or more of a CPU, MPU, GPU, ASIC, FPGA, DSP, and a general-purpose computer. The processor 140 may be a purpose-built controller or may be a general-purpose computing device that is adapted to be a controller. Examples of a non-transitory computer readable memory include but are not limited to RAM, ROM, CD, DVD, Blu-Ray, hard drive, networked attached storage (NAS), an intranet connected non-transitory computer readable storage device, and an internet connected non-transitory computer readable storage device. The controller 140 may include a plurality of processors that are both included in the shaping system 100 and in communication with the shaping system 100. The processor 140 may be in communication with a networked computer 140a on which analysis is performed and control files such as a drop pattern are generated. In an embodiment, there are one or more graphical user interface (GUI) 141 on one or both of the networked computer 140a and a display in communication with the processor 140 which are presented to an operator and/or user.

Either the shaping head 120, the substrate positioning stage 106, or both varies a distance between the mold 110 and the substrate 102 to define a desired space (a bounded physical extent in three dimensions) that is filled with the formable material 124. For example, the shaping head 120 may apply a force to the template 108 such that mold 110 is in contact with the formable material 124. After the desired volume is filled with the formable material 124, the radiation source 126 produces actinic radiation (e.g., UV, 248 nm, 280 nm, 350 nm, 365 nm, 395 nm, 400 nm, 405 nm, 435 nm, etc.) causing formable material 124 to cure, solidify, and/or cross-link; conforming to a shape of the substrate surface 130 and the shaping surface 112, defining a patterned layer on the substrate 102. The formable material 124 is cured while the template 108 is in contact with formable material 124, forming the patterned layer on the substrate 102. Thus, the shaping system 100 uses a shaping process to form the patterned layer which has recesses and protrusions which are an inverse of the pattern in the shaping surface 112. In an alternative embodiment, the shaping system 100 uses a shaping process to form a planar layer with a featureless shaping surface 112.

The shaping process may be done repeatedly in a plurality of imprint fields (also known as just fields or shots) that are spread across the substrate surface 130. Each of the full field imprint fields may be the same size as the mesa 110 or just the pattern area of the mesa 110. The pattern area of the mesa 110 is a region of the shaping surface 112 which is used to imprint (shape) patterns on a substrate 102 which are features of the device or are then used in subsequent processes to form features of the device. The pattern area of the mesa 110 may or may not include mass velocity variation features (fluid control features) which are used to prevent extrusions from forming on imprint field edges. In an alternative embodiment, the substrate 102 has only one imprint field (shaping field) which is the same size as the substrate 102 or the area of the substrate 102 which is to be patterned with the mesa 110. In an alternative embodiment, the imprint fields overlap. As noted above, some of the imprint fields may be partial imprint fields or small partial imprint fields which intersect with a boundary of the substrate 102.

The patterned layer may be formed such that it has a residual layer having a residual layer thickness (RLT) that is a minimum thickness of formable material 124 between the substrate surface 130 and the shaping surface 112 in each imprint field. The patterned layer may also include one or more features such as protrusions which extend above the residual layer having a thickness. These protrusions match the recesses 114 in the mesa 110.

### Template

FIG. 2A is an illustration of a template 108 (not to scale) that may be used in an embodiment. The shaping surface 112 may be on a mesa 110 (identified by the dashed box in FIG. 2A). The mesa 110 is surrounded by a recessed surface 244 on the front side of the template. The mesa 110 has a mesa height hr. The mesa height hr may between 1-200 μm. Mesa sidewalls 246 connect the recessed surface 244 to shaping surface 112 of the mesa 110. The mesa sidewalls 246 surround the mesa 110. In an embodiment in which the mesa is round or has rounded corners, the mesa sidewalls 246 refers to a single mesa sidewall that is a continuous wall without corners. In an embodiment, the mesa sidewalls 246 may have one or more of a perpendicular profile; an angled profile; a curved profile; a staircase profile; a sigmoid profile; a convex profile; or a profile that is combination of those profiles. FIG. 2B is a perspective view of the template 108 (not to scale) showing the mesa edges 210e. FIG. 2B illustrates that the intersection of the mesa sidewalls 246 and the recessed surface 244 may have some curvature due to the process of etching away material form a template precursor to form the mesa 110 on the template 108. The template 108 may have a square planar shape with a template width WT as illustrated in FIGS. 2A-B. In an alternative embodiment, the template width WT is a characteristic width and a planar shape of the template 108 may be a rectangle, parallelogram, polygon, or circle, or some other shape. The template width WT may be between 10-450 mm.

### Shaping Process

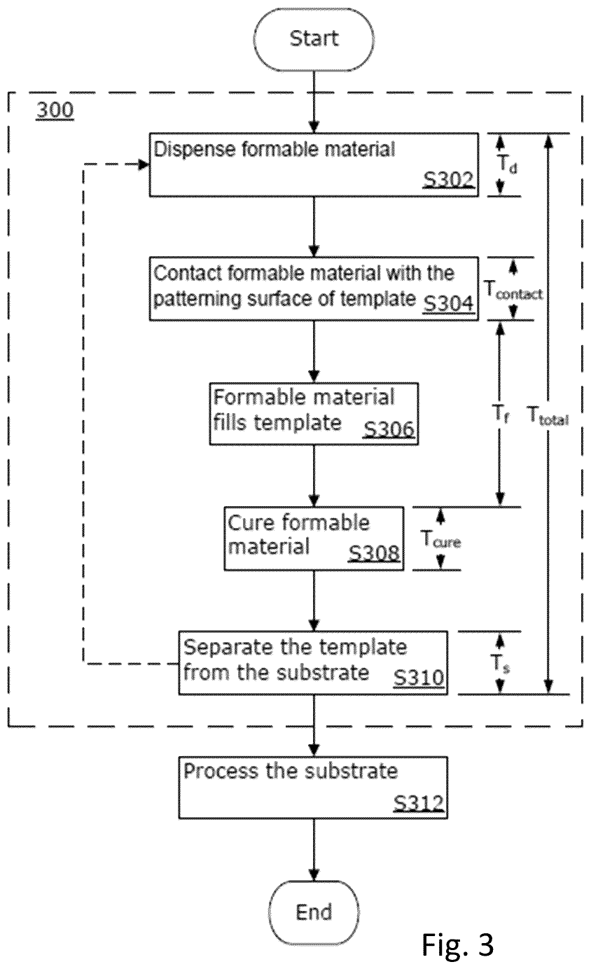

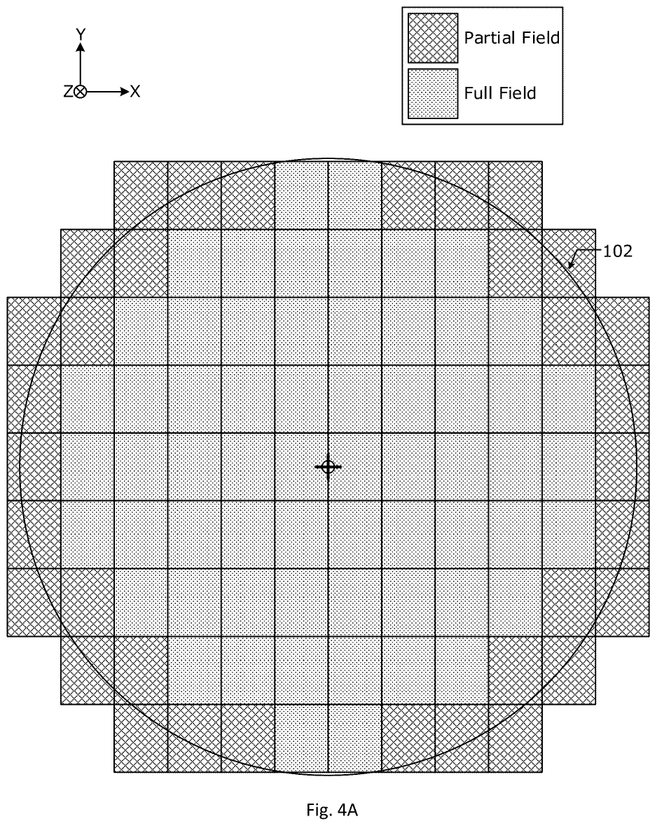

FIG. 3 is a flowchart of a method of manufacturing an article (device) that includes a shaping process 300 performed by the shaping system 100. The shaping process 300 can be used to form patterns in formable material 124 on one or more imprint fields (also referred to as: pattern areas or shot areas). The shaping process 300 may be performed repeatedly on a plurality of substrates 102 by the shaping system 100. The processor 140 may be used to control the shaping process 300.

In an alternative embodiment, the shaping process 300 is used to planarize the substrate 102. In which case, the shaping surface 112 is featureless and may also be the same size or larger than the substrate 102.

The beginning of the shaping process 300 may include a template mounting step causing a template conveyance mechanism to mount a template 108 onto the template chuck 118. The shaping process 300 may also include a substrate mounting step, the processor 140 may cause a substrate conveyance mechanism to mount the substrate 102 onto the substrate chuck 104. The substrate may have one or more coatings and/or structures. The order in which the template 108 and the substrate 102 are mounted onto the shaping system 100 is not particularly limited, and the template 108 and the substrate 102 may be mounted sequentially or simultaneously.

In a positioning step, the processor 140 may cause one or both of the substrate positioning stage 106 and/or a dispenser positioning stage to move an imprinting field i (index i may be initially set to 1) of the substrate 102 to a fluid dispense position below the fluid dispenser 122. The substrate 102, may be divided into N imprinting fields, wherein each imprinting field is identified by a shaping field index i. In which N is the number of shaping fields and is a real positive integer such as 1, 10, 62, 75, 84, 100, etc. {N∈Z+}. In a dispensing step S302, the processor 140 may cause the fluid dispenser 122 to dispense formable material based on a drop pattern onto an imprinting field. In an embodiment, the fluid dispenser 122 dispenses the formable material 124 as a plurality of droplets. The fluid dispenser 122 may include one nozzle or multiple nozzles. The fluid dispenser 122 may eject formable material 124 from the one or more nozzles simultaneously. The imprint field may be moved relative to the fluid dispenser 122 while the fluid dispenser is ejecting formable material 124. Thus, the time at which some of the droplets land on the substrate may vary across the imprint field i. The dispensing step S302 may be performed during a dispensing period T_{d} for each imprint field i.

In an embodiment, during the dispensing step S302, the formable material 124 is dispensed onto the substrate 102 in accordance with a drop pattern. The drop pattern may include information such as one or more of position to deposit drops of formable material, the volume of the drops of formable material, type of formable material, shape parameters of the drops of formable material, etc. In an embodiment, the drop pattern may include only the volumes of the drops to be dispensed and the location of where to deposit the droplets.

After, the droplets are dispensed, then a contacting step S304 may be initiated, the processor 140 may cause one or both of the substrate positioning stage 106 and a template positioning stage to bring the shaping surface 112 of the template 108 into contact with the formable material 124 in a particular imprint field. The contacting step S304 may be performed during a contacting period T_{contact} which starts after the dispensing period Ta and begins with the initial contact of the shaping surface 112 with the formable material 124. In an embodiment, by the beginning of the contact period T_{contact} the template chuck 118 is configured to bow out the template 108 so that only a portion of the shaping surface 112 is in contact with a portion of the formable material. In an embodiment, the contact period T_{contact} ends when the template 108 is no longer bowed out by the template chuck 118. The degree to which the shaping surface 112 is bowed out relative to the substrate surface 130 may be estimated with the spread camera 136.

During a filling step S306, the formable material 124 spreads out towards the edge of the imprint field and the mesa sidewalls 246. The edge of the imprint field may be defined by the mesa sidewalls 246. How the formable material 124 spreads and fills the mesa may be observed via the field camera 136 and may be used to track a progress of a fluid front of formable material. In an embodiment, the filling step S306 occurs during a filling period T_{f}. The filling period T_{f} begins when the contacting step S304 ends. The filling period T_{f} ends with the start of a curing period Tc. In an embodiment, during the filling period T_{f} the back pressure and the force applied to the template are held substantially constant. Substantially constant in the present context means that the back pressure variation and the force variation is within the control tolerances of the shaping system 100 which may be less 0.1% of the set point values.

In a curing step S308, the processor 140 may send instructions to the radiation source 126 to send a curing illumination pattern of actinic radiation through the template 108, the mesa 110, and the shaping surface 112 during a curing period Tc. The curing illumination pattern provides enough energy to cure (polymerize) the formable material 124 under the shaping surface 112. The curing period Tc is a period in which the formable material under the template receives actinic radiation with an intensity that is high enough to solidify (cure) the formable material. In an alternative embodiment, the formable material 124 is exposed to a gelling illumination pattern of actinic radiation before the curing period Tc which does not cure the formable material but does increase the viscosity of the formable material.

In a separation step S310, the processor 140 uses one or more of: the substrate chuck 104; the substrate positioning stage 106, template chuck 118, and the shaping head 120 to separate the shaping surface 112 of the template 108 from the cured formable material on the substrate 102 during a separation period Ts. If there are additional imprint fields to be imprinted, then the process moves back to step S302. In an alternative embodiment, during step S302 two or more imprint fields receive formable material 124 and the process moves back to steps S302 or S304.

In an embodiment, after the shaping process 300 is finished additional semiconductor manufacturing processing is performed on the substrate 102 in a processing step S312 so as to create an article of manufacture (e.g., semiconductor device). In an embodiment, each imprint field includes a plurality of devices.

The further semiconductor manufacturing processing in processing step S312 may include etching processes to transfer a relief image into the substrate that corresponds to the pattern in the patterned layer or an inverse of that pattern. The further processing in processing step S312 may also include known steps and processes for article fabrication, including, for example, inspection, curing, oxidation, layer formation, deposition, doping, planarization, etching, formable material removal, dicing, bonding, packaging, mounting, circuit board assembly, and the like. The substrate 102 may be processed to produce a plurality of articles (devices).

### Layout of Fields on Substrate

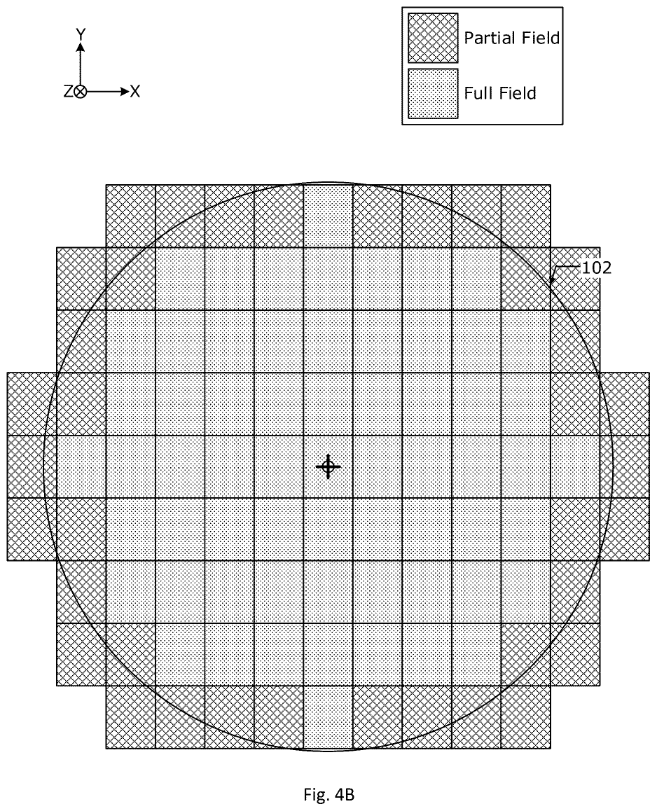

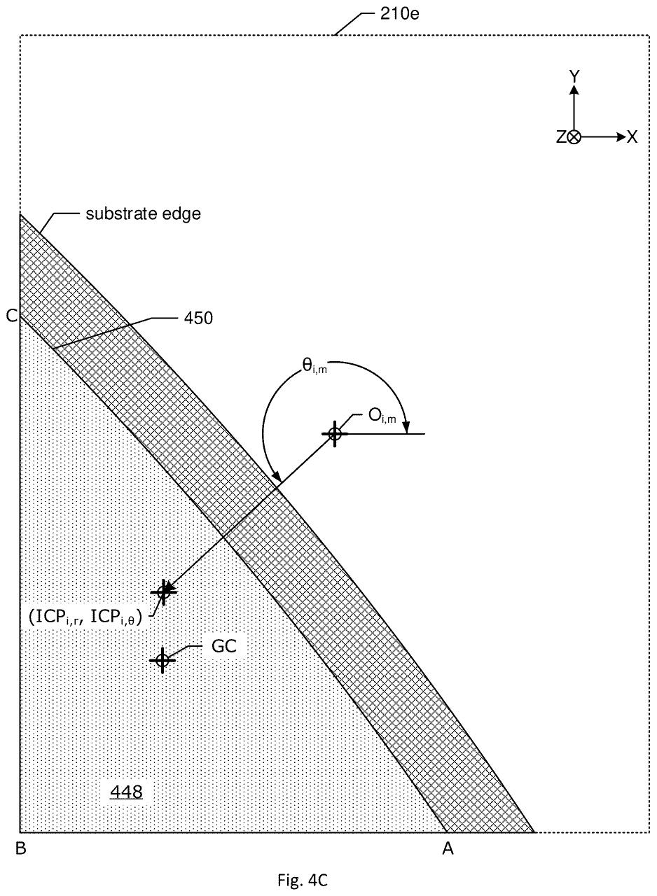

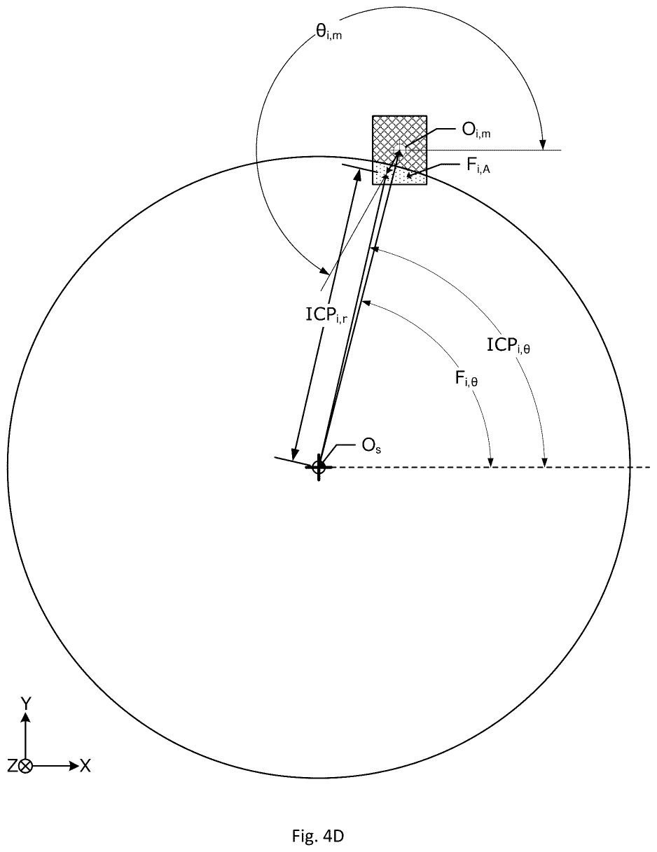

The shaping process 300 can be used in a step and repeat manner to shape a film with a template 108 in a plurality of fields across the substrate 102. The substrate 102 and a patterning area (mesa 110) of a template 108 may have different shapes and sizes. For example, the substrate 102 may have a region to be patterned that is circular, elliptical, polygonal, or some other shape. The mesa 110 is typically smaller than the substrate 102 and has a different shape then the substrate 102. The substrate 102 is divided into a plurality of full fields and a plurality of partial fields/small partial fields as illustrated in FIGS. 4A-B. As discussed above, the full fields are the same size as the mesa 110 or patterning area (shaping surface) of the mesa. That is, the entire surface area of the mesa 110 is equal to the area of one full field such that the total surface area of the shaping surface overlaps the substrate. The partial fields and small partial fields are those fields on the edge of the substrate in which the edge of the region to be patterned on the substrate intersects with the patterning area of the mesa (shaping surface), such that the shaping surface overlaps an edge of the substrate. As noted above, a partial field is a field whose area is less than the area of a full field, which is also less than the entire surface area (shaping surface) of the mesa 110. These fields may be divided into multiple categories based on their shape and/or area relative to the full field. A subset of those partial fields maybe categorized as small partial fields. A partial field may be defined as having a surface area that is less than an entire surface area of the mesa 110, may be defined as having a surface area that is 5% to 99% of the entire surface area of the mesa, or may be defined as having a surface area that is 10% to 95% of the entire surface area of the mesa. A small partial field may be defined as having a surface area that is equal to 50% or less (or 35% or less) of the area of a full field, which is also 50% or less (or 35% or less) of the entire surface area of the mesa 110.

### Small Partial Fields

FIG. 4C is an illustration of a particular small partial field 448 on a substrate 102 in the coordinate system of the mesa 110. In FIG. 4C the mesa edges 210e are illustrated as dotted lines. FIG. 4C also shows the mesa origin Oᵢ,m of the coordinate system of the mesa which is at the center of the mesa 110. A patternable area edge 450 is shown inset from the substrate edge. In an embodiment, the patternable area edge 450 may be inset from the substrate edge by between 0 to 3 mm. The non-patterned area is illustrated with a diamond gird pattern in FIG. 4C. The width of the non-patterned area may be determined by an edge treatment of the substrate 102 which may have been treated to have rounded, beveled, or chamfered edges. The substrate 102 may also have undergone numerous previous processes which cause the edge to have a random unpredictable pattern. The substrate 102 may also have an orientation feature such as a notch or a flat edge.

As illustrated in FIG. 4C the extent of the particular small partial field 448 is defined on two sides by the mesa edge 210e which intersect at a vertex B. The extent of the small partial field 448 is also defined by the arc of the patternable area edge 450. The arc of the patternable area edge 450 may be defined as a portion of a circle, an ellipse, a spline, a polygon, or other geometric quantity that can be used to define a shape of the patternable area edge 450. The arc of the patternable area edge 450 intersects the mesa edges 210e at vertices A and C. This is an exemplary small partial field. The small partial field may have other shapes, which have at least on curved edge and 1 or more straight edges.

### Target Initial Contact Point

The shaping process 300 is controlled using numerous parameters. In an embodiment, one of the process parameters used during the contacting step S302 is the target initial contact point (ICP) for each field i (ICPᵢ={ICP_{i,θ}, ICP_{i,r}}). In an embodiment, polar coordinates relative to the substrate center (Oₛ) may be used to describe target ICP. The location of the target ICPᵢ may also be described as angle θ_{i,m} relative to center of the mesa O_{i,m}. In an alternative embodiment, another coordinate system may be used. The target ICP is the point in the field in which the template 108 should be brought into initial contact with formable material 124 on the substrate 102. The template 108 is bowed out by the template chuck 118 so that only a small portion of the template 108 is brought into contact with the formable material 124 at the target ICP. The bowing of the template is reduced as the template is brought closer to the substrate, until the template is flat, this is done to allow gas to escape during the contacting step S304 and to ensure that the formable material spreads in a controlled manner.

For full fields, the target ICP is at the center of the full field the mesa O_{i,m}. For partial fields, determining the target ICP is more complicated which depends on the shape and area of the partial field and the location of the partial field relative to the center of the substrate (Oₛ). For certain partial fields (e.g., those having an area that is 50% to less than 100% of the area of a full field) the target ICP may be at the same point as the full field or somewhere within the initial contact area. For other partial fields (e.g., those having an area that is 25%-50% of the area of a full field), the target ICP may be determined by calculating a geometric center (GC) or a centroid of the partial field. There are several methods that may be used for determining the GC. One method of estimating the GC is to use a method of intersecting meridians. Another method is to approximate the edge of the partial field using a function. The function may be defined in a piecewise manner and be continuous over the partial field. Integration may then be used to estimate a geometric center of the partial field. A third method of identifying the GC is to minimize distances from the GC to the farthest corners of the partial field.

The GC does not work as well for small partial fields. One method of determining a target ICP for small partial fields is described in US Patent Publication No. 2023-0014261 which is hereby incorporated by reference. As noted above, in an embodiment a partial field may be categorized as a small partial field 448 if it has an area that is less than a fractional area threshold for example 50% of the area of a full field or 35% of the area of a full field. For an alternative embodiment, the fractional area threshold may have a different value for example one of: 1%; 5%; 10%; 15%; 20%; 25%; 30%; 45%; 50% etc. In an embodiment, the target ICP is not the GC for small partial fields and the target ICP is coincident with the center of the mesa or could alternatively be the GC for partial fields that are not categorized as small partial fields.

As illustrated in FIGS. 4A-B different layouts of imprint fields results in different sizes and shapes of partial fields. The partial fields can have complex shapes with 1 to 4 four straight edges and 1 curved edge that meet at 2-5 vertexes for the example where the mesa is a quadrangle, and the substrate is a circle. When determining ICP control values for a partial field it is necessary to know the shape of the partial field. The traditional method of describing the shape of a partial field is to identify positions of all of the vertexes of the shape and the shape of lines connecting all these vertexes. Another method of describing a partial field is as the intersection of two shapes in which the size, shape, and relative positions of these shapes are listed. While this would provide a complete description of the partial field it is not necessary for purposes of determining ICP control values. A partial field shape description Fᵢ for a partial field i can be simplified to just two or three values. For example, a partial field shape description set Fᵢ may include: the area of the partial field shape relative to the area of a full field (F_{i,A}); and an azimuthal angle that represents the angle in the plane of the substrate of a center of the mesa relative to the middle of the substrate (F_{i,e}) (Fᵢ={F_{i,A}, F_{i,e}}) as illustrated in FIG. 4D. Also illustrated in FIG. 4D in the target ICP for the imprint field i (ICPᵢ={ICP_{i,r}, ICP_{i,e}}). As illustrated in FIG. 4D the azimuthal coordinate of the imprint field i (ICP_{i,e}) is different than the azimuthal coordinate of the partial field shape description (F_{i,e}) although in some circumstances they may be the same.

### Method of Determining ICP Control Values

A method for determining ICP control values/parameters is disclosed in U.S. Pat. App. Pub No. 2024/0329542, filed Mar. 28, 2023(hereinafter, “the '542 publication”), which is incorporated by reference herein it its entirety. In particular, the section of the '542 publication titled “Method of Determining ICP control values” is the most relevant portion. The shaping process 300 includes a contacting step S304. As noted in the '542 publication, the contacting step S304 includes receiving a set of contact control values Vᵢ for a partial field i from a processor 140. The set of contact control values Vᵢ may include: a template cavity pressure P_{T} applied to a portion of a template during initial contact of the template 108 with formable material 124 on a substrate 102 which causes the template 108 to be curved with radius of curvature of the template R_{T}; a set of substrate pressures (P_{Sa}, P_{Sb}, and P_{Sc}) applied to a portion of the substrate during initial contact of the template with formable material on the substrate which causes the substrate 102 in the partial field to be curved with a radius of curvature Rₛ; and a tilt (θ_{T}) of the template relative to the substrate during initial contact of the template with formable material on the substrate. The '542 publication provides a flowchart of an ICP control value determination process for small partial fields 448. By implementing the method described in the '542 publication, a set of calibration data Cⱼ associated with a specific imprint process j including the following data may be established: the tilt of the template (θ_{j,T}); one or more substrate pressure control values (P_{j,Sa}, P_{j,Sb}, and P_{j,Sc}); template cavity pressure (P_{j,T}); area of the partial field (F_{j,A}); and azimuthal angle of the partial field (F_{j,θ}). As noted in the '542 publication, the superset of calibration data C may include 10s; 100s or 1000s of sets of calibration data Cⱼ.

As explained in the '542 publication, the ICP control value determination process may include a control condition determination step in which the set of contact control values Vᵢ which allow the template 108 to initially contact the formable material 124 at the ICP_{i,D} are determined based on the partial field description Fᵢ, and the superset of calibration data C. The control condition determination step may output a set of contact control values Vᵢ which may then be used in a step S304 to imprint partial field i. The set of contact control values Vᵢ may include: a template cavity pressure P_{i,T}; a set of substrate pressures (P_{i,Sa}, P_{i,Sb}, and P_{i,Sc}); and a template tilt (θ_{i,T}).

### Initial Contact Control Values (Control Parameters)

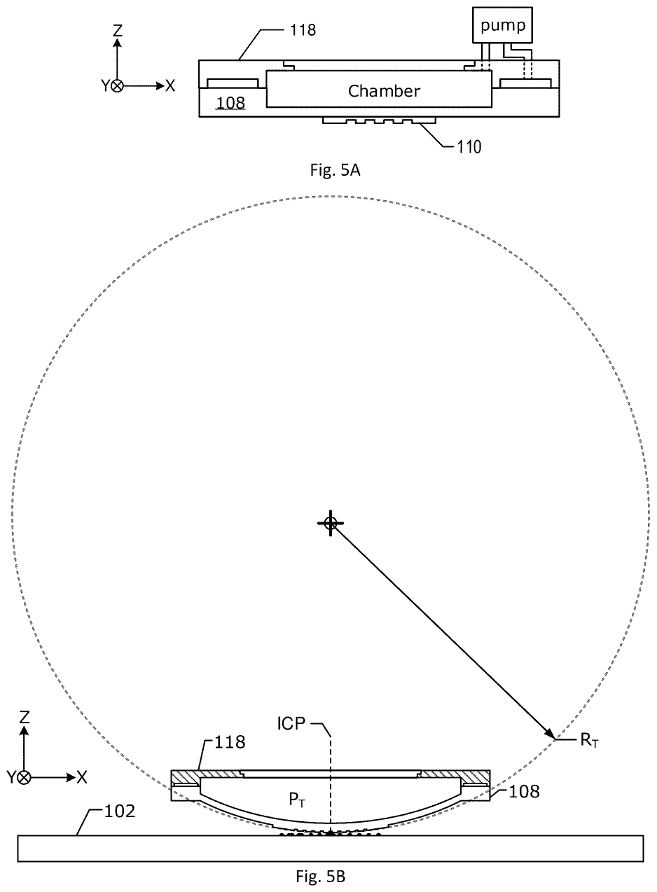

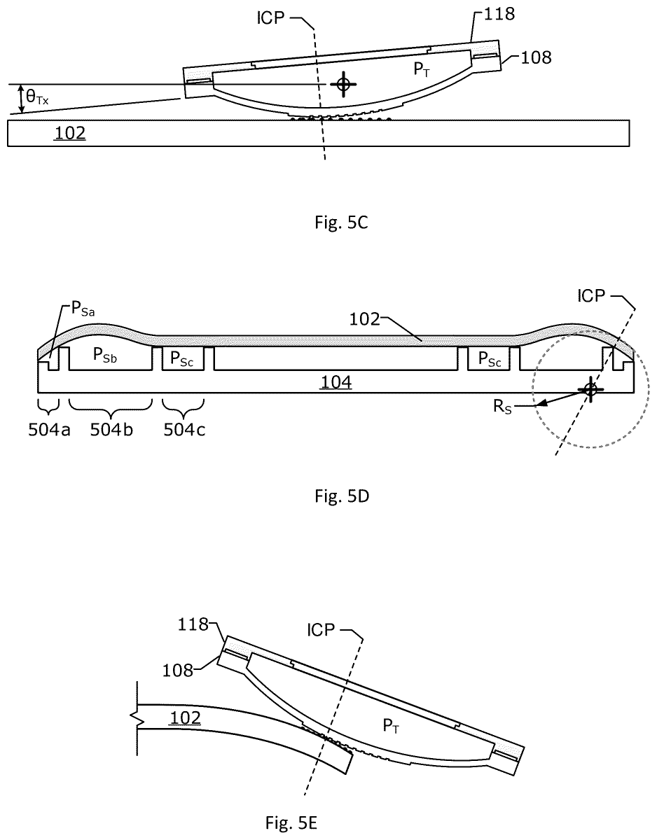

As discussed in the '542 publication, the set of contact control values Vᵢ for an imprint field i may include a template back pressure (P_{i,T}) that is applied by the template chuck 118 to a back surface of the template which bows out the template 108 when imprinting partial field i. FIG. 5A is an illustration of a pump connected to an exemplary template chuck 108 for holding a template 108 details of which are described in US Patent Publication No. 2017/0165898 which is hereby incorporated by reference in its entirety. The template chuck 118 may include one or more vacuum portions which hold the template 108 and a chamber portion which can be used to bow out template 108 as illustrated in FIG. 5B when it is contacting a full field i. By increasing the pressure in the chamber above the ambient pressure of the shaping surface 112, the template 108 is bowed out causing the shaping surface 112 to have a curvature that may be approximated by a radius of curvature of the template (R_{T}) at the ICP. The radius of curvature of the template R_{T} is an approximate representative of a shape of the shaping surface 112 at the ICP. A polynomial (for example a fourth order polynomial) may also be used to approximate the shape of the shaping surface 112 in the region of the ICP at the time of initial contact. A finite element model or other simulation model may be used to determine a shape of the shaping surface under different control conditions.

The control conditions may include a tipping angle of the template (θ_{Tx} rotation of the template about the x-axis) and a tilting angle of the template (θ_{Ty} rotation of the template about the y-axis), which together are the template control angles (θ_{i,T}={θ_{i,Tx}, θ_{i,Ty}}) relative to the substrate as illustrated in FIG. 5C when imprinting a full field i. In an embodiment, θ_{Tx} may be a function G of θ_{Ty} and one or both components of the partial field description F of the imprint field i (θ_{i,Tx}=G(θ_{i,Ty}, Fᵢ)). In which case only one component of the template control angles needs to be known. The function G may be determined experimentally or through simulation such that certain conditions are maintained. The imprint head 120 may include a plurality of actuators that are used to position the template 108 relative to the substrate 102 these plurality of actuators can also be used to tilt the shaping surface 112 relative to the substrate 102. FIG. 5C shows the tilt of a reference surface (front surface of the template chuck) relative to the substrate 102 which is at the same angle as shaping surface 112 when it is not bowed out.

The control conditions may include a set of substrate chuck control values supplied to the substrate chuck 104. The substrate chuck 104 may deform a shape of the substrate 102. As illustrated in FIG. 5D, the substrate chuck 104 may be a zone chuck in which different zones (for example outer zone 504a, first inner zone 504b, second inner zone 504c, etc.) may be supplied with different amounts of positive or negative pressure which causes the substrate to be deformed by between 1-10 μm. The substrate chuck 104 has at least 2 zones but may have 3, 4, 5, 6, 7, 8, 9, 10, or more zones. For example, positive pressure may be supplied to the first inner zone 504b while negative pressures are supplied to the outer zone 504a and the second inner zone 504c. As with the template the shape of the substrate surface 130 may be approximately represented by a radius of curvature of the substrate (Rₛ) at the ICP. A polynomial (for example a fourth order polynomial) may also be used to approximate the shape of the shaping surface 112 in the region of the ICP at the time of initial contact. A finite element model or other simulation model may be used to determine a shape of the shaping surface under different control conditions.

The control conditions (a template cavity pressure P_{T} for controlling the radius of curvature of the template R_{T}; substrate pressures P_{Sa}, P_{Sb}, and P_{Sc} for controlling the radius of curvature of the substrate Rₛ; template tilts Orx and θ_{Ty}; etc.) may be adjusted in combination or independently to control where the ICP is on the small partial field 448 as illustrated in FIG. 5E. The control conditions may include additional parameters which describe the shapes and orientations of the shaping surface 112 at ICP and the substrate surface 130 at ICP. The control parameters may include a plurality of control values and/or trajectories (pressures, currents, voltages, binary control signals, etc.) which are used to determine the shapes and orientations of the shaping surface 112 at ICP and the substrate surface 130 at ICP. The applicant has found that there are typically multiple different solutions to the selection of control conditions to achieve a specific ICP. The selection of which of these solutions is appropriate may depend upon the small partial field size, overlay constraints, alignment constraints, defectivity, process time, etc. This will also have an impact on which control conditions are adjusted as explained in the '542 publication. As explained in the '542 publication, the adjusting control conditions may be performed by adjusting template cavity pressure P_{T} while keeping the other control conditions at default setting(s) depending on the partial field area F_{i,A} and/or the azimuthal angle of the partial field (F_{i,e}).

The amount of pressure that is supplied to the chamber depends on the desired radius of curvatures (R_{T}, R_{S}) at ICP and during the filling step S306 which may be determined based on reducing non-fill defects caused by gas not escaping during the filling step S306 for a given fill time. There are control limitations on the control parameters based on the mechanical characteristics of the template 108, the substrate 102, and the shaping system 100. These limitations prevent: the recessed surface 244 of the template from contacting the substrate surface 130 or an applique surrounding the substrate; and/or the shaping surface 112 from contacting the applique surrounding the substrate. In an alternative embodiment, the ICP is chosen within the ICP range based on limitations on the control parameters. These limitations may be determined experimentally, and/or using a finite element model or other simulation methods. For example, when both the template and substrate are flat the template angle can be calculated using trigonometry as described in equation (1) below. Once the shape of a bowed out shaping surface 112 and/or shape of bowed out substrate surface 130 are determined coordinate transformations may be used to determine the limitations. The relationship between θ_{i,Tx} and θ_{i,Ty} is also described in equation (1) below for an ideal value for θ_{i,Tx} and θ_{i,Ty}. The applicant has found that an ideal solution is not always effective and other values for θ_{i,Tx} and θ_{i,Ty} must be determined through simulation and experimentation.

$$\begin{matrix}{θ}_{max} = {tan}^{- 1} ( 2 \frac{{h}_{T}}{{w}_{T}} ) \\ {θ}_{i , Tx} = \{ \begin{matrix}{θ}_{max} sig ( cos ( {θ}_{i , m} ) ) , & cos ( {θ}_{i , m} ) > sin ( {θ}_{i , m} ) \\ \frac{{θ}_{i , T y}}{tan ( {θ}_{i , m} ) sig ( sin ( {θ}_{i , m} ) )} , & cos ( {θ}_{i , m} ) \leq sin ( {θ}_{i , m} )\end{matrix} \\ {θ}_{i , T y} = \{ \begin{matrix}{θ}_{i , Tx} tan ( {θ}_{i , m} ) sig ( sin ( {θ}_{i , m} ) ) , & cos ( {θ}_{i , m} ) > sin ( {θ}_{i , m} ) \\ {θ}_{max} sig ( sin ( {θ}_{i , m} ) ) , & cos ( {θ}_{i , m} ) \leq sin ( {θ}_{i , m} )\end{matrix}\end{matrix} \qquad ( 1 )$$

Generating the Superset of Calibration Data

[symbol]

As discussed in the '542 publication each individual element of the superset of calibration data Cⱼ should include: control values Vⱼ; a partial field description Fⱼ; and the initial contact point ICPⱼ. Each set of calibration data Cⱼ may be determined via experimentation. In which a series of experiments are performed at a series of different partial fields as illustrated in FIG. 5F. For each partial field j with a specific partial field description (Fⱼ) multiple experiments are performed with different sets of control values Vⱼ that each produce a different ICPⱼ. Examples of such experiments are described in the '542 publication.

### Shaping Method

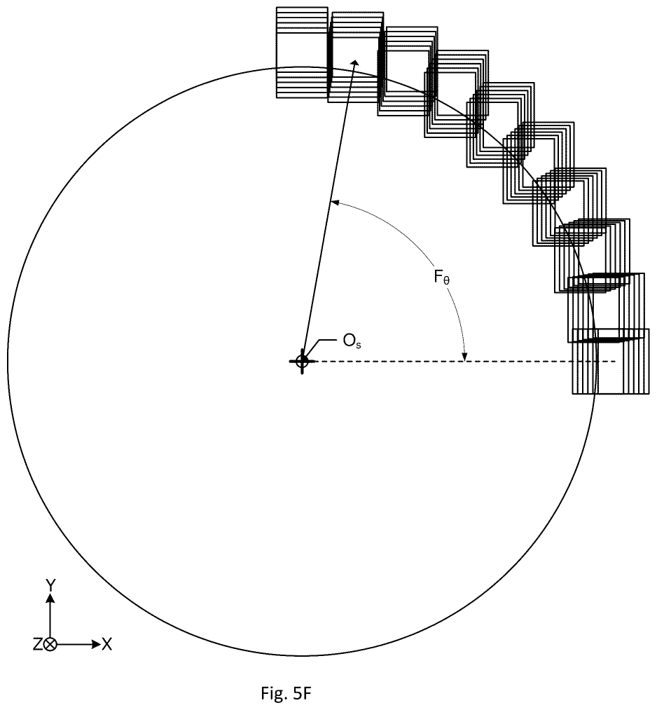

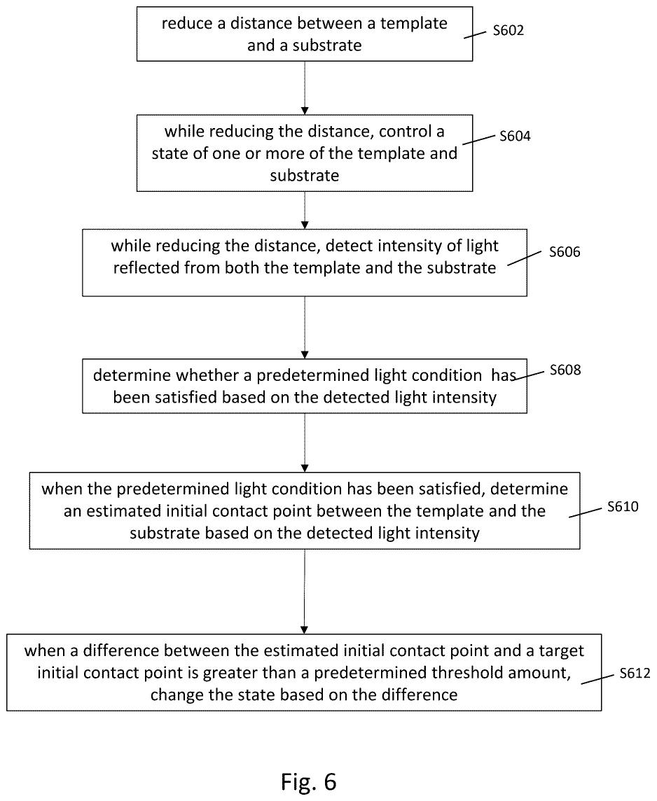

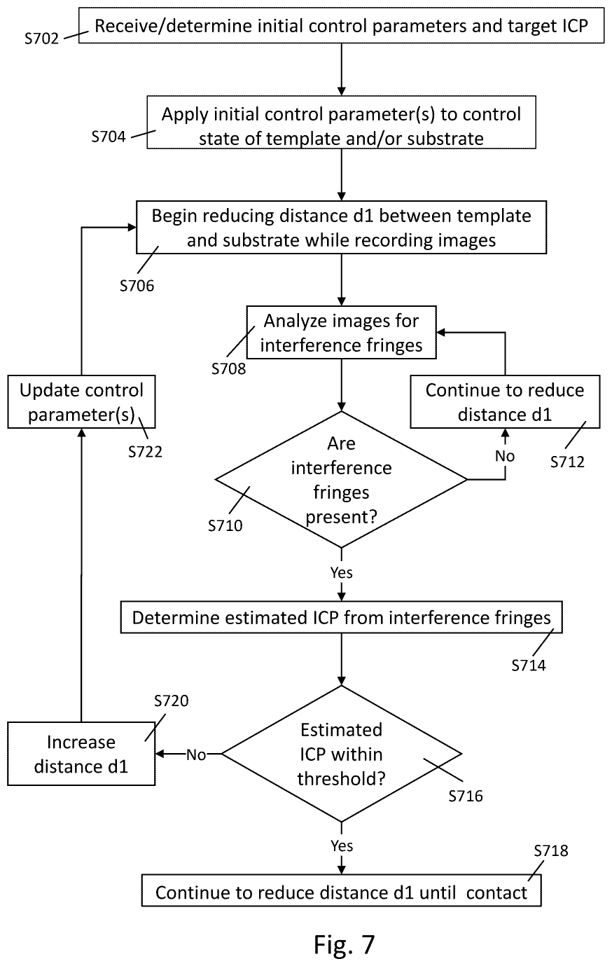

FIG. 6 is a flowchart of a shaping method 600 in accordance with an example embodiment. FIG. 7 is a flowchart of a shaping method 700, which illustrates and example detailed implementation of the shaping method 600.

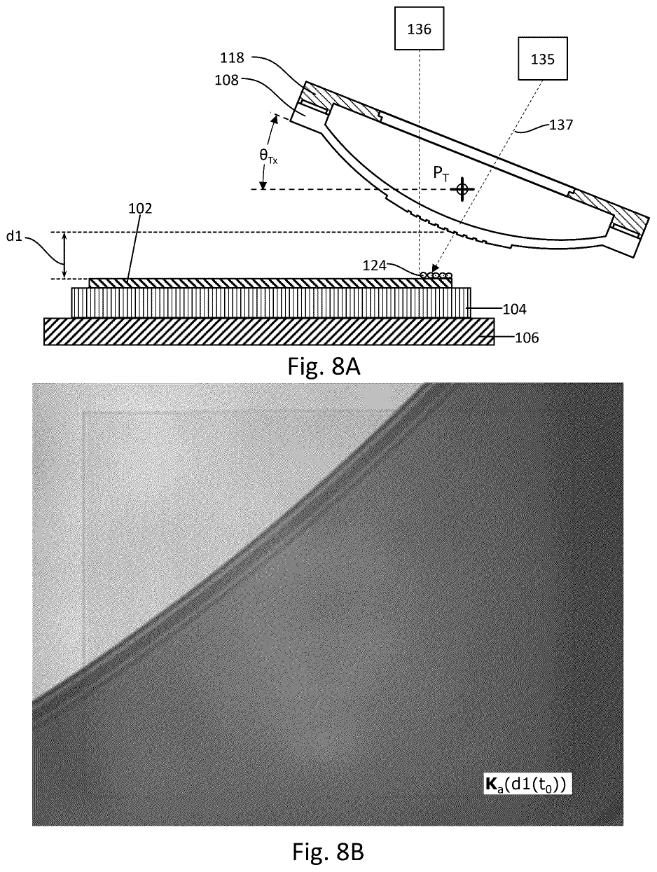

The shaping method 600 begins with step S602 where a distance d1 between the template 108 and the substrate 104 is reduced. The distance d1 can be a distance between the shaping surface 112 and the substrate surface 130 at the ICP as illustrated in FIGS. 8A-12A in the imaging direction of the field/spread camera (?). The distance d1 can also be a distance between a template reference surface and a substrate reference surface. The template reference surface maybe for example a template chucking surface or a surface parallel to the template chucking surface. The substrate reference surface maybe for example a substrate chucking surface or a surface parallel to the substrate chucking surface. The distance d1 may be reduced by moving the template 102 toward the substrate 104 with the substrate 104 being stationary, by moving the substrate 104 toward the template 102 with the template 102 being stationary, or by moving both toward each other in which neither the template 102 nor the substrate 104 is stationary. The way the template and/or substrate can be moved is discussed above. While the distance d1 is reduced, the method may perform step S604 and step S606.

In step S604, while the distance d1 is being reduced, the state of one or more of the template 102 and the substrate 104 is controlled. That is, in step S604, while reducing the distance d1, in one example embodiment only the state of the template 102 may be controlled, in another example embodiment only the state of the substrate 104 may be controlled. In yet another example embodiment both the states of the template 102 and the substrate 104 may be controlled. The control of the of the states is performed by implementing one or more of the control parameters discussed above. That is, the control parameters may be the above-discussed template cavity pressure P_{T} for controlling the radius of curvature of the template R_{T}; substrate pressures P_{Sa}, P_{Sb}, and P_{Sc} for controlling the radius of curvature of the substrate Rₛ; template tilts θ_{Tx} and Ory; etc. As will be discussed below with respect to FIG. 7, there may be more than one instance of performing the step of reducing the distance while controlling the state of the template and/or substrate. In the initial instance in which the distance d1 is reduced for the first time, the initial control parameters are those determined through the above-described methods to attempt to achieve the above-discussed target ICP. In other words, the initial control parameters that are those that have been predetermined to attempt to achieve a predetermined target ICP. The method described herein can be implemented to adjust one or more of the control parameters to achieve an actual ICP that is closer to the target ICP.

Turning to FIG. 7, step S702 to step S706 correspond to step S602 and step S604 of FIG. 6. As indicated in FIG. 7, the method 700 may start with step S702 where the target ICP and the initial control parameters corresponding to the target ICP (e.g., one or more of template cavity pressure, substrate pressures, template tilts) is received or determined. The target ICP and the corresponding initial control parameters are determined as described above. Importantly, as described above, for a partial field/small partial field, the control parameters and target ICP are unique for the partial field/small partial field. The method 700 may then proceed to step S704 where the initial control parameters are applied to the template and/or substrate to control the template and/or substrate. That is, as noted above, depending on which initial control parameters are being used for the target ICP, the state of the template, the state of the substrate, or both are controlled. The method 700 may then proceed to step S706 where the distance d1 between the template and the substrate are reduced. The initial control parameters are used to control the state of the template and/or substrate as the distance d1 is reduced.

FIG. 8A is an illustration of a template and substrate at the moment corresponding to step S604 of FIG. 6 and step S706 of FIG. 7. As shown in FIG. 8A, the template is positioned to imprint a partial field. Thus, the shaping surface of the template overlaps with an edge of the substrate in FIG. 8A. In the illustrated example embodiment of FIG. 8A, the template 108 is in the process of moving downward toward the substrate 104 (thereby reducing the distance d1), while the control parameter for template cavity pressure (P_{T}) is being implemented to control the state of the template. In the example, the template cavity pressure and the template tilt are the only controls being implemented for simplicity, but as noted above any combination of control parameters can be implemented to control the states of the template and/or substrate.

At the same time the distance d1 is being reduced, the method 600 may proceed to step S606 where light intensity reflected from both the template and the substrate is detected. While the distance d1 is being reduced visible measurement light 137 is emitted from the light source 135. The measurement light 137 may have a measurement wavelength λ such as peak wavelength of 470 nm of the light received by the field camera 136). As shown in FIG. 8A, the measurement light 137 passes through the template 108, which is transparent, and reaches the substrate 102. As the measurement light 137 passes through the template 108 and reaches the substrate 102, some of the light is reflected by the template 108 (the reflectance of template may be for example 2-5%) and some of the measurement light is reflected by the substrate 102 (the reflectance of the substrate may be for example 20-40%). These reflections cause an interference pattern known in the art as interference fringes or Newton's rings which are measurable with the field camera 136. That is, the interference pattern caused by the reflected light appears as a plurality of concentric rings, i.e., a plurality of expanding rings having the same center point. The appearance of the interference fringes and the intensity of the interference fringes changes based on the distance d1 between the shaping surface 112 and substrate surface 130. The substrate 102 may include multiple coatings which produce multiple reflections which may have an impact on the ability to predictably estimate d1 in all situations based solely on the interference fringes. The applicant has found that despite this limitation reliable relative estimates of the distance d1 can be obtained with the field camera 136. When the distance is d1 is relatively large (e.g., on the scale of 20λto 30λ) or greater) there are no perceivable interference fringes. This will depend on: the reflectance of the substrate; the reflectance of the template; curvature of the template; curvature of the substrate; and the sensitivity of the field camera 136. When the distance d1 is relatively small (e.g., on the scale of 20λ to 30λ), the interference fringes are perceivable and become clearer as d1 gets smaller.

As noted above, the field camera/spread camera 136 may be configured to gather images of the template and substrate as measurement light 137 is emitted thereon by the light source 135. The field camera 136 can be setup to obtain a video at specified frame rate. Non-limiting examples of the specified frame rate are: 15 Hz, 30 Hz, 60 Hz, 120 Hz, 164 Hz, 240 Hz and 1000 Hz. Each frame of the video may be considered an image. Each image can be analyzed by the processor 140. As d1 is reduced, the field camera/spread camera 136 repeatedly takes images Kₐ(d1(t)) as a function of time of template and substrate as the measurement light 137 is reflected by both the template and the substrate. FIG. 8B shows an example image Kₐ(d1(t₀)) taken when the template 108 is at the position shown in FIG. 8A. As seen in FIG. 8B there is not yet any perceivable presence of interference fringes, i.e., there are no concentric rings appearing in the image of FIG. 8B. The example image Kₐ(d1(t₀)) can be used as a background-only reference image.

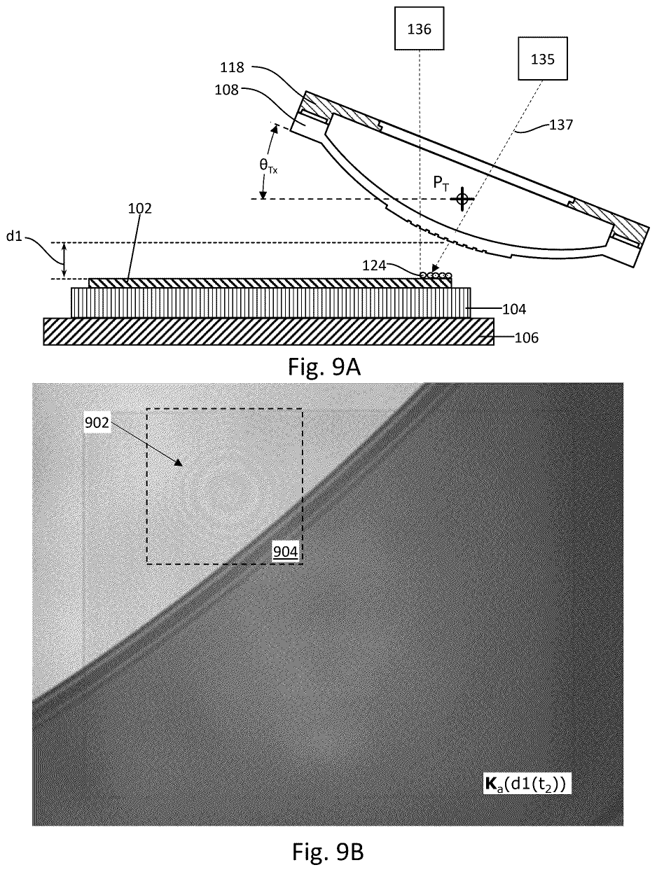

FIG. 9A shows a moment after FIG. 8A where the distance d1 has been reduced and the template 108 is closer to the substrate 102 than in the FIG. 8A. FIG. 9B shows an example image Kₐ(d1(t₂)) taken when the template 108 is at the position d1 at time t₂ shown in FIG. 9A. As seen in FIG. 9B there is a faint appearance of interference fringes 902, i.e., the interference fringes 902 are beginning to become perceivable within the box 904.

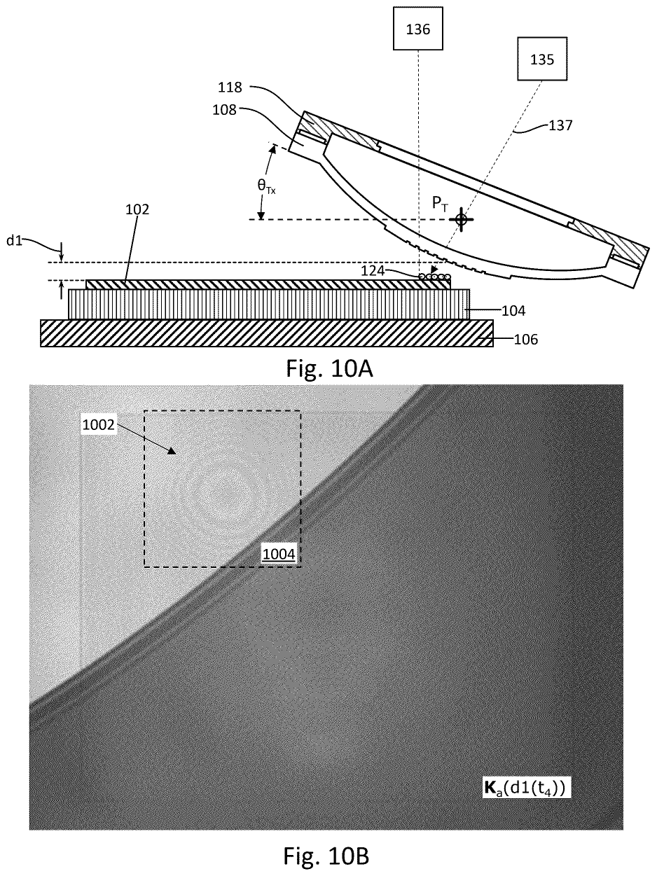

FIG. 10A shows a moment after FIG. 9A where the distance d1 has been reduced at time t₄ and the template 108 is closer to the substrate 102 than in the FIG. 9A. FIG. 10B shows an example image Kₐ(d1(t₄)) taken when the template 108 is at the position shown in FIG. 10A. As seen in FIG. 10B there is a clearer appearance of interference fringes 1002, i.e., the interference fringes 1002 within the box 1004 are more perceivable than compared to FIG. 9B.

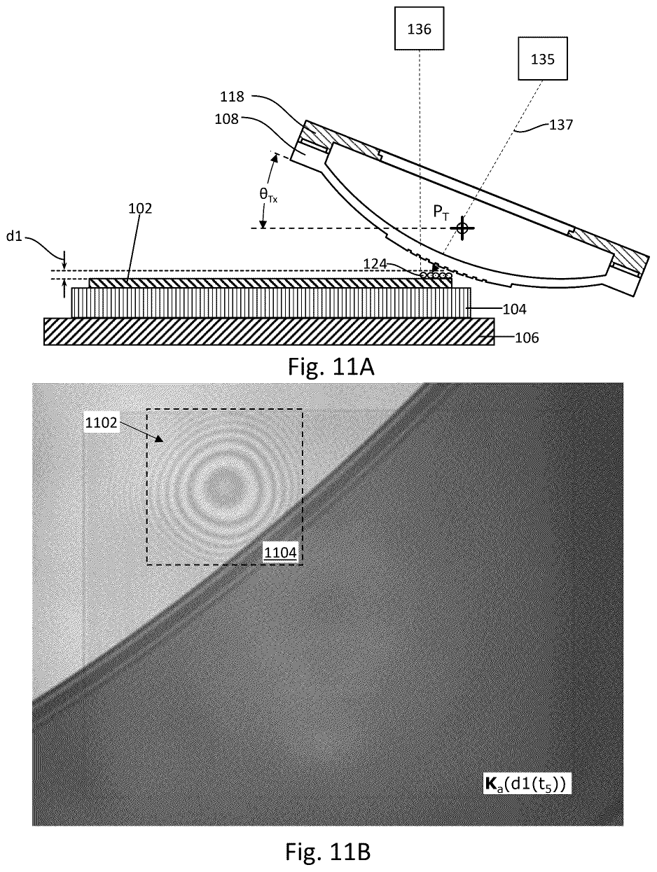

FIG. 11A shows a moment after FIG. 10A where the distance d1 has been reduced at time t₅ and the template 108 is closer to the substrate 102 than in the FIG. 10A. FIG. 11B shows an example image Kₐ(d1(t₅)) taken when the template 108 is at the position shown in FIG. 11A. As seen in FIG. 11B there is an even clearer appearance of interference fringes 1102, i.e., the interference fringes 1102 within the box 1104 are clearer than compared to FIG. 10B.

Step S606 of the method 600 includes measuring the light intensity (light intensify information) of the reflected light throughout the period of reducing the distance d1. That is, the camera 136 will take an image (detect the light intensity) multiple times as the distance d1 is reduced, for example 2, 5, 10 to 300 times. This step also corresponds to step S706 of the method 700 where images are recorded using the camera 136.

For each image taken, the method may proceed to step S608 where it is determined whether a predetermined light condition has been satisfied based on the detected light intensity. The predetermined light condition is whether the interference fringes have reached a sufficient presence to indicate that the template is very close to touching, but has not already touched, the substrate. In other words, by analyzing/processing the light intensity information recorded by the camera, and using predetermined threshold information, it is possible determine for each image whether the interference fringes are sufficiently present.

The steps for performing the analysis for each individual image as the distance d1 is reduced are steps S708 to S710 in FIG. 7. In step S708 the first image is processed/analyzed. In step S710 it is determined whether the interference fringes are sufficiently present. If the answer to step S710 is “No,” then the method proceeds to S712 where the distance d1 is continued to be reduced. The method then returns to step S708 where the next image is analyzed and the determination of whether interference fringes are sufficiently present is made for that image. This process of steps S708 to S712 repeats until the answer to step S710 is “Yes.”

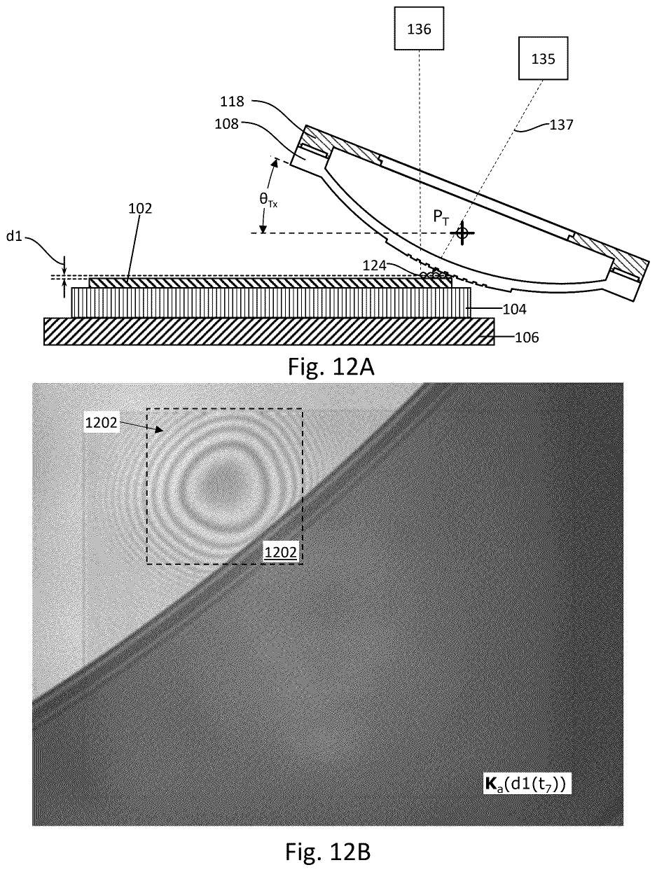

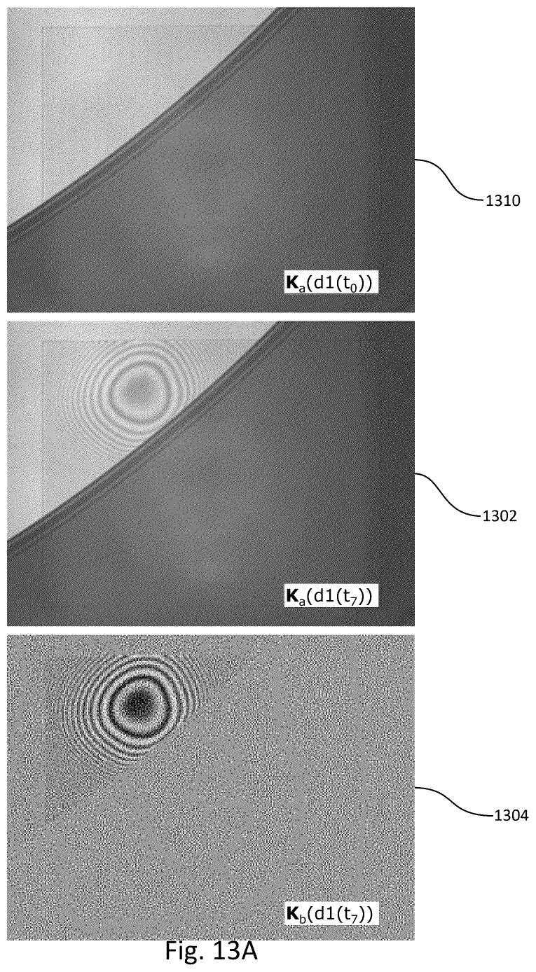

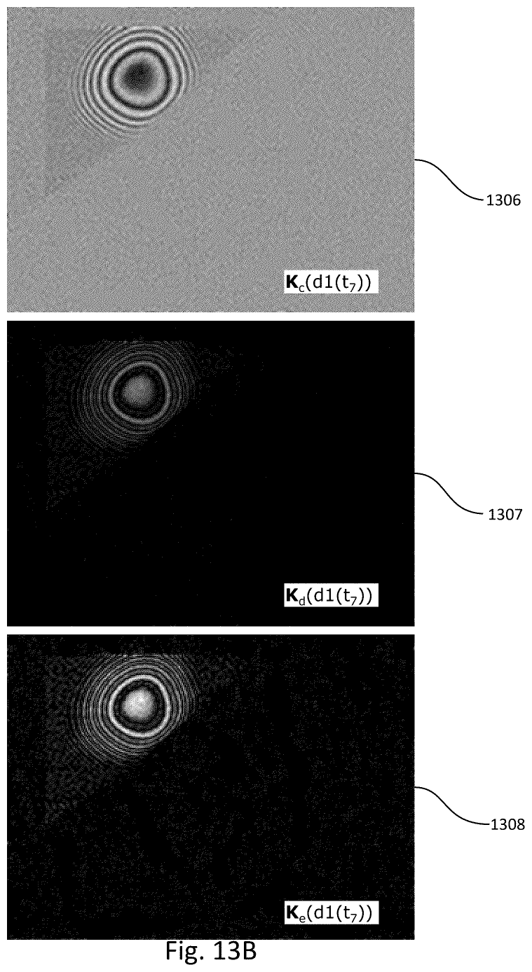

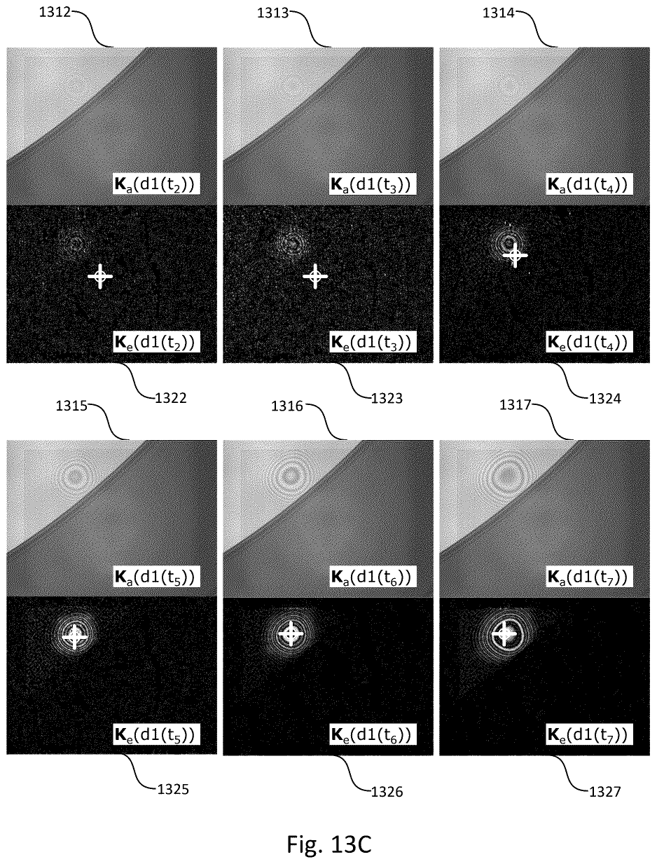

The process for analyzing the images and determining whether the interference fringes are sufficiently present is as follows. FIGS. 13A-B show a series of images demonstrating the steps of processing an image 1317 Kₐ(d1(t₇)) of interference fringes that was obtained after contact (FIG. 12B, as part of determining whether a predetermined light condition has been satisfied (step S608) and also part of determining whether interference fringes are present (step S710). The process for analyzing the images can include capturing background-only image 1310 Kₐ(d1(t₀)) of the partial field to be imprinted by the template. This background-only image 1310 Kₐ(d1(t₀)) should be obtained while the template is sufficiently far away so as to not produce visible fringes in background-only image 1310. This can be captured prior to template approaching the substrate. The first image 1302 Kₐ(d1(t₇)) of FIG. 13A is the original image of FIG. 12B taken from the camera 136 when the template 108 is at the distance from the substrate 102 shown in FIG. 9A. The second image 1304 of FIG. 13A is after a processing step where the background of the image Kₐ(d1(t₀)) has been subtracted from the first image 1302 (K_{b}(d1(t₇))=Kₐ(d1(t₇))—Kₐ(d1(t₀)). The background is subtracted by using a background-only image that was taken by the camera earlier in the process before the distance d1 has been reduced to a point where interference fringes are known to not be detectable. That is, the background-only image is a reference image that has all of the light information that is present even before the distance d1 has begun to be reduced or has only been reduced by a small amount. The distance d1 when the reference image is obtained should be for example at least 10 μm but can be more. By subtracting the background-only reference image Kₐ(d1(t₀) from the first image 1302 only the light intensity information related to interference fringes (if any) remains in the second image 1304 along with some background noise. The subtraction may be performed by subtracting the light intensity of the background-only reference image from the first image 1302 on a pixel-by-pixel basis. The example of FIG. 13A is when the distance d1 is relatively small (i.e., the template is relatively close to the substrate at this moment), and the interference fringes are very visible, but this information is obtained to late in the imprinting process to be useful.

Next, the image processing may include denoising and filtering the second image 1304 to arrive at the third image 1306. This is achieved using a standard denoising/filtering technique such as by setting the light intensity information of each individual pixel as an average of the pixels surrounding it (K_{b}(d1(t₇)→K_{c}(d1(t₇)). Examples of denoising/filtering techniques include but are not limited to: convolution spatial filtering; convolution neural networks; and mathematical morphology. The convolution spatial filtering technique can use any one of variety of kernels. Examples of kernels include but are not limited to: a box filter; a Gaussian filter; sharpen; ridge; and adaptive filter. For example the denoising/filtering process may include two steps of: non-local means denoising; and a 2-pole low pass Butterworth filter. The filtered image is then rescaled (K_{c}(d1(t₇)→Kₐ(d1(t₇)). The image K_{c} (d1(t₇) with fringes has an effective DC component. This image K_{c} (d1(t₇)) is rescaled such that the DC component is removed. For example, the median value of the image K_{c} (d1(t₇)) is found and made to be integer value 0 to produce an AC component image 1307 shown in FIG. 13B.

$${K}_{d} ( d 1 ( t 7 ) ) = {K}_{c} ( d 1 ( t 7 ) ) - median ( {K}_{c} ( d 1 ( t 7 ) ) ) \qquad ( 1 )$$

Then, the AC component image 1307 is normalized to arrive at the fourth image 1308 shown in FIG. 13B (Kₐ(d1(t₇)→Kₑ(d1(t₇)). The AC component image 1307 can be normalized by rescaling over a fixed range (for example 0-255 which is the natural range for an unsigned 8-bit integer image) as illustrated in normalized image 1308 in FIG. 13B. Normalizing is achieved using a standard technique such as by averaging the light intensity across all of the pixels in the image and then subtracting the average from each pixel. FIG. 13C illustrates the result of this image analysis process being performed on 6 frames as the template is approaching the substrate. For example, image 1312 obtained at time t₂(frame number 2) can be analyzed using the method described above to obtain normalized image 1322 (Kₐ(d1(t₂)→Kₑ (d1(t₂)). For example, image 1313 obtained at time t3 (frame number 3) can be analyzed using the method described above to obtain normalized image 1323 (Kₐ(d1(t3)→Kₑ (d1(t3)). For example, image 1314 obtained at time t₄(frame number 4) can be analyzed using the method described above to obtain normalized image 1324 (Kₐ(d1(t₄)→Kₑ (d1(t₄)). For example, image 1315 obtained at time t₅ (frame number 5) can be analyzed using the method described above to obtain normalized image 1325 (Kₐ(d1(t₅)→Kₑ(d1(t₅)). For example, image 1316 obtained at time t6 (frame number 6) can be analyzed using the method described above to obtain normalized image 1326 (Kₐ(d1(t₆)→Kₑ (d1(t₆)). For example, image 1317 obtained at time t₇(frame number 7) can be analyzed using the method described above to obtain normalized image 1327 (Kₐ(d1(t₇)→Kₑ (d1(t₇)). As seen in FIG. 13A, because the distance d1 is relatively large (i.e., the template is relatively far away from the substrate at this moment), and the interference fringes are barely present, the fourth image 1304 does not result in much indication that interference fringes are present.

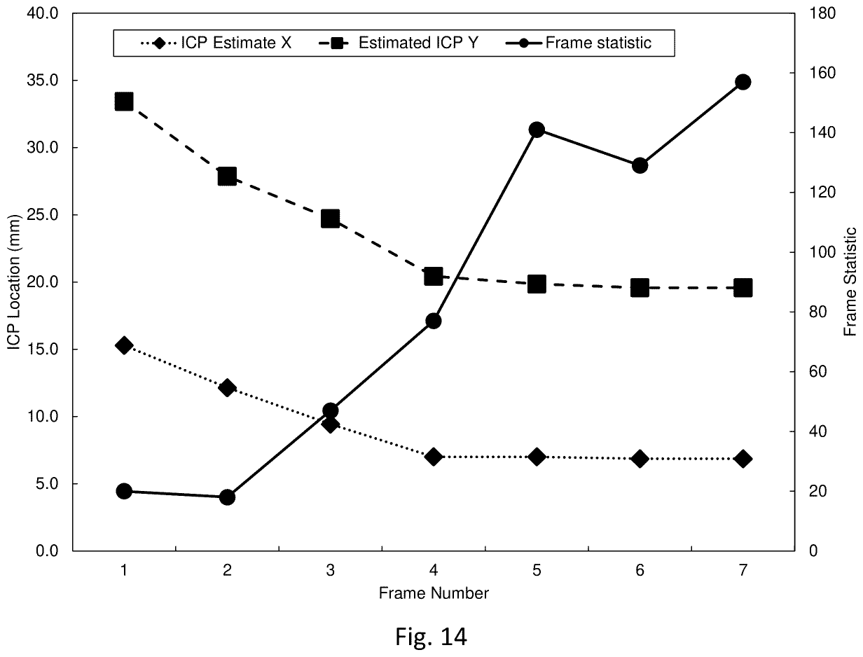

After generating the fourth image 1304, a frame statistic is determined from the fourth image 1304. The frame statistic may be representative of a signal-to-noise ratio (SNR) for example. There are various methods of calculating the frame statistic. One method of calculating the frame statistic is to normalize the image and calculate a median intensity of the normalized image. Another method of calculating the frame statistic is a difference between the median intensity and the minimum intensity. Another method of calculating the frame statistic is to calculate the mean intensities of the fourth image divided by the standard deviation of the intensities of the fourth image. Another method of calculating the frame statistic is the median divided by the range. Another method that is representative of the frame statistic is maximum intensity divided by the minimum intensity. Another method includes creating a histogram and identifying statistical properties of one or more peaks in the histogram. Another method that is representative of the statistic is maximum intensity minus the minimum intensity. There can be limited time and computational resources in which to make a meaningful determination of the frame statistic such that a decision such that low computational representations of the frame statistic that are accurate enough are useful. FIG. 14 illustrates how the frame statistic varies with frame number.

A frame statistic value that is considered to adequately represent when interference fringes are sufficiently present, but before contact of the template with substrate has occurred, can be predetermined through experimentation. For example, a representative partial field may be imprinted and the same process described above of taking images and calculating the frame statistic can be performed. The images of the representative partial field can be taken through the period in which d1 is reduced including all the way through contact with the substrate. The images that correspond to the moment just before contact and the images corresponding to contact or later are identified. Then, the frame statistic values for those images that have interference fringes sufficiently present, but before contact, are acquired. Thus, the range of frame statistic values that correlate with the moment when the interference fringes are sufficiently present are known. In an example embodiment, the target frame statistic range may be 20 to 35, for example when the image has been normalized to 0-255 range. When the frame statistic is much higher, this indicates that the template is too close to the substrate or has already contacted the substrate. For example an frame statistic of about 140 or more can be used as the range to conclude that the template is too close to the substrate or that contact has already occurred. The applicant has found that when the frame statistic is below a lower threshold value (for example 80 or 127 when normalized to a range of 0-255) the interference fringes supply misleading information about the location of the initial contact point. While when the frame statistic is above an upper threshold values (for example 150 when normalized to a range of 0-255) the template is too close to the substrate or in contact with the substrate so that it is too late to change the set of contact control values Vᵢ.

In the example of FIGS. 9B, 10B, 11B, and 12B the determination is made that the frame statistic is 18, 77, 141, and 157 by following the above steps. Because the frame statistic is lower than for example 80 or 127(when the image is normalized 0-255), the determination is made that interference fringes are not yet sufficiently present. The threshold value will be determined based on the range on which the frame is normalized to it is typically around middle of the range but can be above or below depending on the system. That is, at the moment the template 108 is located relatively far from the substrate 102 at the moment shown in FIG. 9A, the above process determines that the interference fringes are not yet sufficiently present. Accordingly, for the moment shown in FIGS. 9A, 9B, the conclusion of step S608 of the method 600 is that the predetermined light condition has not been satisfied. Similarly, for the moment shown in FIGS. 9A, 9B, the conclusion of step S710 of the method 700 is “no.” While the position of FIGS. 9A, 9B is used as the example in the above description, the same process is repeated many (i.e., tens, hundreds, or thousands of times) including the moment shown in FIGS. 8A/8B. The analysis of FIG. 8B would have the same result as the analysis of FIG. 9B because the distance d1 is greater at that moment to in FIGS. 8A, 8B than distance d1 at the moment t₂ in FIGS. 9A, 9B.

Because the conclusion of step S710 is “no”, the method 700 proceeds to step S712 where the distance d1 is reduced further. Then the analysis of steps S708 and S710 are repeated. These steps continue to be repeated until the answer to the presence of interference fringes are determined to be yes. FIGS. 10A and 10B show an example moment where the distance d1 has been reduced further as compared to the moment of FIGS. 9A and 9B. The same analysis discussed above is performed at this moment, as well as may other moments in between. FIG. 10B shows an example where the interference fringes have become more visible, but would still result in an frame statistic value much closer to the target frame statistic range, but still below it. Thus, for the image Kₐ(d1(t₄)) of FIG. 10B, the result of step S710 would still be “no”. Similarly in step S608, the predetermined light condition would have been satisfied.

Because the answer is “no” as step S710 for the image of FIG. 10B, the method may proceed to continue to reduce the distance d1. Eventually the process will arrive at the moment t₅ shown in FIGS. 11A, 11B. At this movement, the distance d1 has been further reduced compared to the moment t₄ in FIGS. 10A, 10B. As shown in FIG. 11B, the interference fringes have become more visible. FIG. 14A shows the same image analysis that was performed in FIG. 13A, except that the image analysis is performed on the image of FIG. 11B. As shown in FIG. 14A, first the background is subtracted from the initial image 1402 (i.e., the image of FIG. 11B) to obtain the image 1404. Then the image 1404 can then be denoised and filter resulting in the image 1406. Finally, the image 1406 is normalized resulting in the image 1408. FIG. 14B shows the image intensity chart prepared in the same manner as the chart of FIG. 13B. In the case of the image of FIG. 11B, the resulting frame statistic is 141, which is within the target frame statistic range of 80-150(when normalized to the range of 0-255). Accordingly, the decision made in step S710 is “yes” that interference fringes is present. Similarly, in step S608 it is determined that the predetermined light condition has been satisfied. Further because the frame statistic is less than 150, it is determined that the template has not yet come into contact with the substrate. In an alternative embodiment, the image analysis to obtain the frame statistic can include a cropping step such that only pixels that are known to be within the partial imprint field are used. When the frame statistic is low the detected position of the ICP will be dominated by the background noise and will tend towards the center of the image or the cropped image.

By arriving at the answer “yes” in FIG. S710, the method 700 may proceed to step S714, where the estimated ICP is determined from the interference fringes. This is also the step S610 of the method 600 where the estimated ICP is determined based on the detected light intensity. More particularly, the ICP is determined from the light intensity data that represents the interference fringes. As noted above, and shown in the figures, the interference fringes appear in the form of concentric circles. The estimated ICP is the center of the concentric circles. Accordingly, a standard analysis tool for finding the center of a circle can be used. Once the center of the circles of the interference fringes is determined, the estimated ICP is known. Step S610 can include calculating a weighted average using the rescaled-DC removed image 1308. The applicant has found that strong fringe intensity are set to a higher value, thus weighted more heavily than the background values in the normalized image 1308. When the fringes are strong enough, but do not form connected line, this estimation of ICP is very accurate. Proximity suitable for ICP judgement can be determined based on the predicted ICP location (using the weighted average method). Scanning only around the predicted ICP location on the normalized image 1308, if the median pixel value is greater than a center of the rescaled range of the image than that is a good indication the signal intensity is strong enough (i.e. frame statistic is high enough) to stop the motion of the template toward the substrate and apply corrections to the set of contact control values Vᵢ. Another method of performing step S610 is to use a find circles type analysis (for example the HoughCircles ( ) function in the Open Source Computer Vision library). There are several well-known methods of finding circles in an image. FIG. 14 is a chart illustrating the estimated ICP in the x and y directions for the frames in FIG. 13C. The estimated ICP represented by a target crosshair overlaid on the normalized image 1308 of each of the frames in FIG. 13C. As illustrated in FIG. 13C the estimated ICP has difficulty identifying the ICP until a frame statistic indicates that the frame statistic is good enough as in frames 5-7 as opposed to frames 2-4 in which the ICP estimate is very. FIG. 14 also illustrates that the when the frame statistic is above a threshold value that is a strong indicator that a frame will provide a good estimate of the ICP, and the estimated ICP can be done with minimal calculations which allow for the ICP to estimated prior to contact.

FIGS. 12A and 12B show an example moment where the distance d1 has been reduced further as compared to the moment of FIGS. 11A and 11B. While the moment t₅ of FIGS. 11A and 11B serve as one example where the interference infringes appear and the analysis results in a suitable frame statistic, FIGS. 12A and 12B show another example moment t₇ that would also have a suitable frame statistic. That is, there are multiple images Kₐ and multiple distances d1 that may satisfy step S710 and allow for the determination of an estimated ICP. FIG. 12B shows an example image Kₐ(d1(t₇)) where the interference fringes 1202 in the area 1204 have become even more visible and would result in an frame statistic value on the higher end of the acceptable predetermined range, but low enough to mean that contact has not yet occurred. Thus, for the image Kₐ(d1(t₇)) of FIG. 12B, the result of step S710 would also be “yes” and the estimated ICP can be used from this example image as well. In an embodiment, a frame statistic that is too high can be indicative that contact has occurred or is about to occur.

After acquiring the estimated ICP, the method 700 may proceed to step S716 where it is determined whether the estimated ICP from step S714 is within a predetermined threshold of the target ICP. The predetermined threshold is predetermined based on the target ICP that was determined above, and for which the corresponding control parameters have been in place during the reduction of the distance to control the state of the template and/or substrate. The predetermined threshold is an acceptable amount of deviation from the target ICP. That is, if the estimated ICP is within the predetermined threshold, then the estimated ICP is close enough to the target ICP to achieve adequate filling performance. On the other hand, if the estimated ICP is outside the predetermined threshold, then the estimated ICP is too far from the target ICP to achieve adequate filling performance. The predetermined threshold may be determined by accuracy requirements of the estimated ICP and time required to estimate the ICP and stopping motion of the template before it makes it contact with the substrate. The predetermined threshold may be 80-149 when the image is normalized to 0-255.

If the estimated ICP is within the predetermined threshold (“yes” in step S716), then the method 700 proceeds to step S718 where the distance d1 is continued to be reduced and the contact with the template and substrate proceeds. That is, when the estimated ICP is close enough to target ICP, then the imprinting proceeds with the initial control parameters setting the state of the template and/or substrate until contact occurs. However, if the estimated ICP is outside the predetermined threshold (“no” in step S716), then the method 700 proceeds to step S720 where the distance d1 is increased. That is, when the estimated ICP is too far from the target ICP, instead of continuing with the imprinting process, the distance d1 between the template and the substrate is increased such that the template and the substrate are farther away from each other than in the previous step. This is because if the estimated ICP is too far from the target ICP, then the resulting imprinting quality will be negatively impacted by unacceptable filling. By increasing the distance d1, and then performing the subsequent steps discussed herein, the estimated ICP can be corrected to be sufficiently close to the target ICP. Increasing the distance d1 may be performed by moving one or both of the template and substrate away from the other.

After increasing the distance d1, the method 700 may proceed to step S722 where the control parameters are updated. That is, one or more of the control parameters that are used to control the state of the template and/or substrate are changed. The example control parameters that may be changed in step S722 are the same parameters noted above, e.g. cavity pressure P_{T} for controlling the radius of curvature of the template R_{T}; substrate pressures P_{Sa}, P_{Sb}, and P_{Sc} for controlling the radius of curvature of the substrate Rₛ; template tilts θ_{Tx} and Ory. Which parameters to change, and how much to change them, may be based on the difference between the estimated ICP determined in step S716. The difference between the estimated ICP and the target ICP may be quantified in terms of both magnitude (i.e., how far off) and direction (i.e., if the estimated ICP is closer or farther from a wafer center relative to the target ICP). In the case that the estimated ICP is closer to the wafer center than the target ICP, then the change to the control parameters may be one or more (including all) of the following: increase cavity pressure P_{T}, decrease substrate pressures P_{Sa}, P_{Sb}, and P_{Sc}, and decrease the template tilts Orx and Ory. In the case that the estimated ICP is farther from the wafer center than the target ICP, then the change to the control parameters may be one or more (including all) of the following: decrease cavity pressure P_{T}, increase substrate pressures P_{Sa}, P_{Sb}, and P_{Sc}, and increase the template tilts θ_{Tx} and θ_{Ty}. The magnitude of the change to the control parameters may be based on the magnitude of the difference in location of the estimated ICP and the target ICP. That is, if the difference is greater between the estimated ICP and the target ICP, the amount of control parameter adjustment will be greater. For example, for 1 kPa of change in cavity pressure, the change in location of the ICP can be expected to be about 1 mm depending on the shaping system and the template 108. A change in 1 kPa of substrate pressures can change the location of the ICP by about 0.8 mm depending on the locations of the vacuum control zones of the substrate chuck 104 relative to the position and shape of the partial field. Prior experimental testing can be performed to correlate how much change in each control parameter will change the ICP. Thus, using this predetermined correlation information, which control parameters to change can be determined, and how much to change the selected control parameters can be determined. Adjusting the template tilt θ_{Tx} can be used to adjust the position of the ICP in the y direction and adjusting the tilt Ory can be used for adjusting the position of the ICP in the x direction.

The above-described step of changing the control parameters corresponds to step S612 of the method 600. That is, in step S612, when the difference between the estimated initial contact point and the target initial contact point is greater than a predetermined threshold amount, the state of the template and/or substrate is changed based on the difference.

As shown in FIG. 7, after updating one or more of the control parameters in step S722, the process starting with step S706 is repeated. The difference in the second cycle is that the control parameters have been changed, which changes the state of the template and/or substate. Thus, the same steps S706 to S714 are repeated to arrive at a new estimated ICP. This process includes once again reducing the distance d1 between the template and the substrate while capturing and analyzing images for interference fringes. As before, following the method 700, eventually a new/updated estimated ICP will be determined. If the new estimated ICP is within the predetermined threshold of the target ICP (the target ICP remaining constant), then the method 700 will terminate on the second cycle at step S718 and complete the imprinting. If the new estimated ICP is still too far from the target ICP then the cycle will repeat again. However, by using the method 700, including changing the control parameters based on the magnitude and direction of the difference between the target ICP and the estimated ICP, it has been found that one instance of updating the control parameters is sufficient to achieve an estimated ICP that is within the predetermined threshold distance from the target ICP.

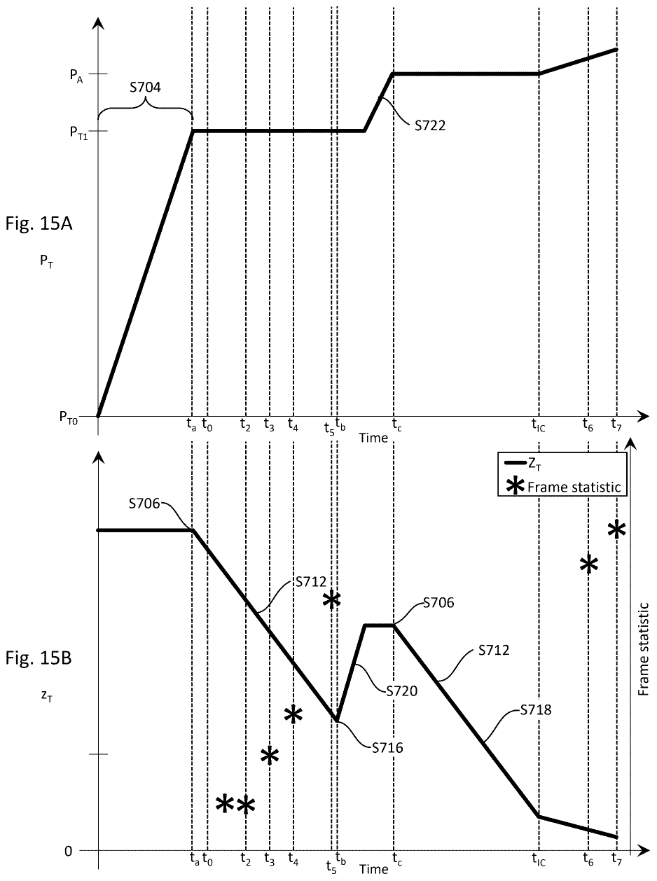

FIG. 15A is timing diagram illustrating how the template cavity pressure control condition may vary over time in an exemplary embodiment of imprinting partial fields and small partial fields. FIG. 15B is a timing diagram illustrating how the template chuck position (ZT) is adjusted during the same period of time as FIG. 15A. The template chuck position (ZT) is correlated with the first distance d1. FIG. 15B also illustrates how the frame statistic varies with time. FIGS. 15A and 15B also show when the initial contact time (tic) is reached. FIG. 15A is a timing diagram illustrating how the template cavity pressure (P_{T}) is adjusted to an initial template bowing pressure (PT1) and then adjusted to an adjusted pressure (PA) prior to the initial contact time (tic). The adjusted pressure (PA) is the change in control parameter described above with respect to step S722. As shown in FIGS. 15A and 15B, from the initial time to the time ta, the template chuck position does not change and the template cavity pressure ramps up to the initial pressure PT1. This aspect of reaching the initial template cavity pressure Pri corresponds to step S704. Thus, time ta corresponds with the completion of step S704 and the beginning of Step S706.

Next, as seen in FIG. 15B, the template position decreases which corresponds to step S706. This proceeds until reaching time tb, during which time the steps S708 to S716 are performed to analyze the images. Upon reaching time to, the template chuck position (ZT) increases during step S720 until the template has reached a safe position at which the template cavity pressure P_{T} increases to a new pressure PA. The increase in template position corresponds to the step S720 and the increase in pressure corresponds to step S722, where PA represents adjusting the control parameter for template cavity pressure. While only template cavity pressure is illustrated for simplicity, the other control parameters mentioned above may also be adjusted as described above when needing to adjust the estimated ICP. Alternatively, the template chuck position (Z_{T}) may be changed while the template cavity pressure (P_{T}) is being increased. The background-only reference image at time to may be obtained after the template cavity pressure (P_{T}) has reached initial template bowing pressure (P_{T1}). Alternatively, the background-only reference image may be obtained in a prior shaping process or earlier in the shaping process. In an alternative embodiment, the background-only reference image may be a simulated image. The substrate chuck may continue to do fine alignment on micron and sub-micron scale after the time to.

After the passing time t_{c}, FIG. 15B shows the template position decreasing again which corresponds to the second instance of performing step S706. As the template begins to move back down the same steps S708 to S716 are also repeated. In the example embodiment illustrated in FIGS. 15A and 15B, the estimated ICP is within the threshold after a single adjustment to the template cavity pressure and the timing chart proceeds to the initial contact time tic. During and after the initial contact time tic the same imprinting process and control of the control parameters described in the incorporated documents. That is, after the template and the substrate come into contact, the same imprinting process is performed, such as described in U.S. Pat. No. 11,614,693. See, for example FIGS. 9A-9G of U.S. Pat. No. 11,614,693 and corresponding description. The image in FIG. 12B was obtained after the initial contact time tic which can be perceived via the non-circular nature of the interference fringes and an increase in the frame statistic.

By performing the above-described methods, it is possible to achieve an actual ICP that is closer to the target ICP as compared to proceeding to contact without performing the above-described method. That is, performing the imprinting using the initial control parameters without performing the above-described method may result in an actual ICP that is too far from the target ICP, which results in inferior filling. The above-described methods minimized or avoids such a situation. Thus, the products/articles produced by following the above-described methods also have superior quality as a result of superior filling.

Further modifications and alternative embodiments of various aspects will be apparent to those skilled in the art in view of this description. Accordingly, this description is to be construed as illustrative only. It is to be understood that the forms shown and described herein are to be taken as examples of embodiments. Elements and materials may be substituted for those illustrated and described herein, parts and processes may be reversed, and certain features may be utilized independently, all as would be apparent to one skilled in the art after having the benefit of this description.

What is claimed is:

1. An imprinting method comprising:
reducing a distance between a template and a substrate;
while reducing the distance:
controlling a state of one or more of the template and substrate; and
detecting intensity of light reflected from both the template and the substrate;
determining whether a predetermined light condition has been satisfied based on the detected light intensity;
in a case of determining that the predetermined light condition has been satisfied, determining an estimated initial contact point between the template and the substrate based on the detected light intensity; and
in a case that a difference between the estimated initial contact point and a target initial contact point is greater than a predetermined threshold amount, changing the state based on the difference.

2. The method of claim 1, wherein in a case that that the difference is less than or equal to the predetermined threshold amount, further reducing the distance without changing the state.

3. The method of claim 2, wherein the further reducing of the distance without changing the state is maintained until the template and the substrate come into contact.

4. The method of claim 1, wherein in a case that determining that the predetermined light condition has not been satisfied, repeating the detecting of the light intensity and repeating the determining of whether a predetermined light condition has been satisfied, until the predetermined light condition has been satisfied.

5. The method of claim 1, wherein in the case that the difference is less than the predetermined threshold amount, increasing the distance.

6. The method of claim 5, wherein after increasing the distance, reducing the distance for a second time while maintaining the changed state.

7. The method of claim 6, wherein while reducing the distance for a second time:
detecting intensity of light reflected from both the template and the substrate;
determining whether the predetermined light condition has been satisfied based on the detected light intensity;
in a case of determining that the predetermined light condition has been satisfied, determining an updated estimated initial contact point between the template and the substrate based on the detected light intensity; and
in a case that a difference between the updated estimated initial contact point and the target initial contact point is less than or equal to the predetermined threshold amount, causing the template and the substrate to come into contact.

8. The method of claim 1, wherein the state of one or more of the template and the substrate is controlled based on a control parameter.

9. The method of claim 8, wherein the control parameter is a parameter selected from the group consisting of a template cavity pressure, a substrate pressure, and a tilt of the template.

10. The method of claim 9, wherein the template cavity pressure controls a radius of curvature of the template and the substrate pressure controls the radius of curvature of the substrate.

11. The method of claim 1, wherein the predetermined light condition is the presence of interference fringes caused by light reflected from both the template and the substrate.

12. The method of claim 11, wherein the predetermined light condition is based on a predetermined range of a frame statistic.

13. The method of claim 12, further comprising:
determining a frame statistic from the detected light intensity reflected from both the template and the substrate; and
wherein determining whether the predetermined light condition has been satisfied is performed by determining whether the determined frame statistic is within the predetermined range of frame statistic.

14. The method of claim 1,
wherein the template has a shaping surface, and
wherein, while reducing the distance, the shaping surface overlaps an edge of the substrate.

15. The method of claim 14,
wherein the shaping surface overlaps the edge of the substrate by an overlap amount, and
wherein the target initial contact point is based on the overlap amount.

16. The method of claim 1, further comprising:
while reducing the distance, emitting visible light toward the template and the substrate,
wherein the light reflected from both the template and the substrate is the emitted visible light.

17. A method of manufacturing an article, comprising:
dispensing formable material on a substrate;
reducing a distance between a template and the substrate;
while reducing the distance:
controlling a state of one or more of the template and substrate; and
detecting intensity of light reflected from both the template and the substrate;
determining whether a predetermined light condition has been satisfied based on the detected light intensity;
in a case of determining that the predetermined light condition has been satisfied, determining an estimated initial contact point between the template and the substrate based on the detected light intensity;
in a case that a difference between the estimated initial contact point and a target initial contact point is greater than a predetermined threshold amount, changing the state based on the difference;
bringing the template into contact with the formable material;
exposing the formable material under the template to actinic radiation;
processing the substrate; and
forming the article from the processed substrate.

18. A imprinting system comprising:
one or more memory; and
one or more processors configured to:
reduce a distance between a template and a substrate;
while reducing the distance:
control a state of one or more of the template and substrate; and
detect intensity of light reflected from both the template and the substrate;
determine whether a predetermined light condition has been satisfied based on the detected light intensity;
in a case of determining that the predetermined light condition has been satisfied, determine an estimated initial contact point between the template and the substrate based on the detected light intensity; and
in a case that a difference between the estimated initial contact point and a target initial contact point is greater than a predetermined threshold amount, change the state based on the difference.
